(19) United States
(12) Patent Application Publication
(10) Pub. No.: US 2024/0387413 A1
(43) Pub. Date: Nov. 21, 2024

(54) SEMICONDUCTOR DEVICE

(71) Applicant: Samsung Electronic Co., Ltd., Suwon-si (KR)

(72) Inventors: Jaejun LEE, Suwon-si (KR); Seil Oh, Suwon-si (KR); Beomyong Kil, Suwon-si (KR); Dongju Kim, Suwon-si (KR); ChangSik Yoo, Suwon-si (KR); Suyoun Lim, Suwon-si (KR); Sangkeum Han, Suwon-si (KR)

(73) Assignee: SAMSUNG ELECTRONICS CO., LTD., Suwon-si (KR)

(21) Appl. No.: 18/592,266

(22) Filed: Feb. 29, 2024

(30) Foreign Application Priority Data
May 15, 2023 (KR) 10-2023-0062173

(51) Int. Cl. H01L 23/60; H01L 23/00; H01L 23/48; H01L 25/065; H01L 29/861

(52) U.S. Cl. CPC H01L 23/60; H01L 23/481; H01L 24/16; H01L 25/0657; H01L 29/8611; H01L 2224/16225; H01L 2225/06541; H01L 2924/12036; H01L 2924/1434; H01L 2924/30205

(57) ABSTRACT

A semiconductor device includes: a semiconductor substrate; a via structure passing through the semiconductor substrate; a first diode including a first impurity zone doped with a first conductivity-type impurity and a second impurity zone doped with a second conductivity-type impurity; and a second diode including a third impurity zone doped with the first conductivity-type impurity and a fourth impurity zone doped with the second conductivity-type impurity, wherein the second conductivity-type impurity is different from the first conductivity-type impurity, and wherein at least one of the first impurity zone, the second impurity zone, the third impurity zone, and the fourth impurity zone overlaps with a keep-out zone of the via structure.

### CROSS-REFERENCE TO RELATED APPLICATION

This application claims benefit of priority to Korean Patent Application No. 10-2023-0062173 filed on May 15, 2023 in the Korean Intellectual Property Office, the disclosure of which is incorporated herein by reference in its entirety.

### BACKGROUND

### 1. Field

The disclosure relates to a semiconductor device.

### 2. Description of Related Art

A semiconductor package includes two or more semiconductor devices that may be mounted on a package substrate in the form of being stacked on each other. The two or more semiconductor devices may respectively include a semiconductor substrate, and may be electrically connected to each other by a via structure, passing through the semiconductor substrate. A signal may be input/output or a power supply voltage may be transmitted through the via structure, and thus, the via structure may be connected to a diode for protecting an internal circuit from electrostatic discharge (ESD).

### SUMMARY

Provided is a semiconductor device capable of preventing defects caused by electrostatic discharge (ESD) inflowing during a processing or a testing by providing a pair of diodes in a keep-out zone (KOZ) of a via structure.

According to an aspect of the disclosure, a semiconductor device includes: a semiconductor substrate; a via structure passing through the semiconductor substrate; a first diode including a first impurity zone doped with a first conductivity-type impurity and a second impurity zone doped with a second conductivity-type impurity; and a second diode including a third impurity zone doped with the first conductivity-type impurity and a fourth impurity zone doped with the second conductivity-type impurity, wherein the second conductivity-type impurity is different from the first conductivity-type impurity, and wherein at least one of the first impurity zone, the second impurity zone, the third impurity zone, and the fourth impurity zone overlaps with a keep-out zone of the via structure.

According to another aspect of the disclosure, a semiconductor device includes: a semiconductor substrate; a via structure passing through the semiconductor substrate; a first diode including a first impurity zone and a second impurity zone; and a second diode including a third impurity zone and a fourth impurity zone, wherein at least one of the first diode and the second diode overlaps with a keep-out zone of the via structure, and wherein a shape of the first diode is different from a shape of the second diode.

According to another aspect of the disclosure, a semiconductor device includes: a first power pad receiving a first power voltage; a second power pad receiving a second power supply voltage lower than the first power supply voltage; a via structure passing through the semiconductor substrate; a signal pad exchanging a signal, the signal pad operatively connected to the via structure; a first diode including a first impurity zone and a second impurity zone, the first diode being connected between the signal pad and the first power pad; and a second diode including a third impurity zone and a fourth impurity zone, the second diode being connected between the signal pad and the second power pad, wherein at least one of the first diode and the second diode is provided in a zone between the via structure and an integrated circuit zone, wherein semiconductor elements are formed in the zone, wherein the semiconductor elements provide an input/output circuit connected to the via structure, wherein each of the first impurity zone, the second impurity zone, the third impurity zone, and the fourth impurity zone comprises a first boundary extending in a first direction that is parallel to an upper surface of the semiconductor substrate and comprises a second boundary extending in a second direction that is parallel to the upper surface of the semiconductor substrate and orthogonal to the first direction, and wherein at least one of the first impurity zone, the second impurity zone, the third impurity zone, and the fourth impurity zone comprises a third boundary extending in a third direction that intersects the first direction and the second direction.

### BRIEF DESCRIPTION OF THE DRAWINGS

The above and other aspects, features, and advantages of the disclosure will be more clearly understood from the following detailed description, taken in conjunction with the accompanying drawings, in which:

FIG. 1 is a schematic diagram illustrating a system including a semiconductor package according to an example embodiment of the disclosure;

FIG. 2 is a schematic diagram illustrating a semiconductor package according to an example embodiment of the disclosure;

FIG. 3 is a diagram illustrating an arrangement relationship between via structures according to an example embodiment of the disclosure;

FIG. 4 is a schematic diagram illustrating a system including a semiconductor package according to an example embodiment of the disclosure;

FIG. 5 is a schematic diagram illustrating a system including semiconductor devices according to an example embodiment of the disclosure;

FIGS. 6 and 7 are schematic diagrams illustrating a semiconductor device according to an example embodiment of the disclosure;

FIGS. 8 and 9 are schematic diagrams illustrating a first diode included in a semiconductor device according to an example embodiment of the disclosure;

FIGS. 10 and 11 are schematic diagrams illustrating a second diode included in a semiconductor device according to an example embodiment of the disclosure;

FIGS. 12 and 13 are diagrams illustrating a semiconductor device according to an example embodiment of the disclosure;

FIG. 14A is a cross-sectional view of the semiconductor device illustrated in FIG. 13 taken along line I-I′ according to an example embodiment of the disclosure;

FIG. 14B is a diagram illustrating a connection relationship with an input/output circuit of the semiconductor device illustrated in FIG. 12 according to an example embodiment of the disclosure;

FIGS. 15 and 16 are diagrams illustrating a semiconductor device according to an example embodiment of the disclosure;

FIGS. 17 to 20 are diagrams illustrating a semiconductor device according to an example embodiment of the disclosure;

FIGS. 21 to 24 are diagrams illustrating a semiconductor device according to an example embodiment of the disclosure;

FIGS. 25 and 26 are diagrams illustrating a semiconductor device according to an example embodiment of the disclosure;

FIGS. 27 and 28 are diagrams illustrating a semiconductor device according to an example embodiment of the disclosure;

FIGS. 29 and 30 are diagrams illustrating a semiconductor device according to an example embodiment of the disclosure;

FIGS. 31 and 32 are diagrams illustrating a semiconductor device according to an example embodiment of the disclosure; and

FIG. 33 is a diagram illustrating a connection between input/output elements of the semiconductor device of FIG. 32 according to an example embodiment of the disclosure.

### DETAILED DESCRIPTION

Hereinafter, preferred example embodiments of the disclosure will be described with reference to the accompanying drawings.

The embodiments described herein are non-limiting example embodiments, and thus, the disclosure is not limited thereto and may be realized in various other forms.

Although the terms “first”, “second”, etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure.

When an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “include” and “comprise”, and the derivatives thereof refer to inclusion without limitation. The term “or” is an inclusive term meaning “and/or”. The phrase “associated with,” as well as derivatives thereof, refer to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. Similarly, the term “set” means one or more. Accordingly, the set of items may be a single item or a collection of two or more items.

In the detailed description, components described with reference to the terms “part”, “unit”, “module”, “block”, “˜er or ˜or”, etc. and function blocks illustrated in drawings will be implemented with software, hardware, or a combination thereof. For example, the software may be a machine code, firmware, an embedded code, and application software. For example, the hardware may include an electrical circuit, an electronic circuit, a processor, a computer, an integrated circuit, integrated circuit cores, a pressure sensor, an inertial sensor, a microelectromechanical system (MEMS), a passive element, or a combination thereof.

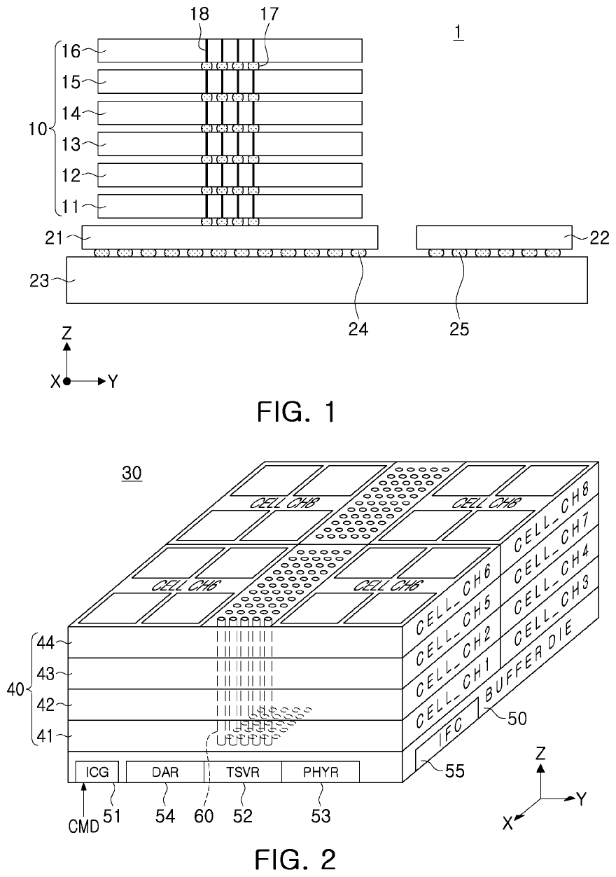

FIG. 1 is a schematic diagram illustrating a system including a semiconductor package according to an example embodiment of the disclosure.

Referring to FIG. 1, a semiconductor package 1 according to an example embodiment may include a plurality of semiconductor devices 10, 21, and 22 and a package substrate 23. The plurality of semiconductor devices 10, 21, and 22 may include a controller 22, a buffer die 21, and a plurality of memory devices 10 (11 to 16) stacked on the buffer die 21. In an example embodiment of the disclosure, each of the plurality of memory devices 10 may include memory cells for storing data and peripheral circuits for controlling the memory cells.

The plurality of memory devices 10 may be stacked on the buffer die 21 in a direction (Z-axis direction in FIG. 1), perpendicular to an upper surface of the package substrate 23. The plurality of memory devices 10 may be electrically connected to each other through a plurality of bumps 17. The plurality of bumps 17 may be disposed or provided between pads formed on one surface of each of the plurality of memory devices 10 to physically and electrically connect a pair of adjacent memory devices 10 to each other.

A semiconductor die, included in each of the plurality of memory devices 10, may include an element zone and an interconnection zone. In the element zone, elements providing a semiconductor substrate, memory cells, and peripheral circuits may be disposed or provided. In the interconnection zone, interconnection patterns connected to the memory cells and peripheral circuits may be disposed or provided. A plurality of via structures 18, included in the semiconductor die, may be through-silicon vias (TSVs), extending from the interconnection zone and passing through the semiconductor substrate.

The plurality of via structures 18 may be formed of a metal material such as copper or the like. As an example, copper may have a coefficient of thermal expansion higher than that of silicon included in the semiconductor substrate. Due to such a difference, thermal stress may occur in the interior of the via structure 18, the semiconductor substrate, and peripheral structures of the via structure 18, and the thermal stress may cause an issue related to reliability of the semiconductor package 1. A zone in which thermal stress may affect the periphery of the via structure may be defined as a keep-out zone (KOZ).

Accordingly, the keep-out zone may be a zone surrounding each of the plurality of via structures 18. The keep-out zone may be a zone in which elements necessary for an operation of the plurality of memory devices 10 are not formed, and an element zone in which elements are disposed or provided around the keep-out zone may be provided. Accordingly, the keep-out zone may be provided between each of the plurality of via structures 18 and the element zone.

The buffer die 21 and the controller 22 may be mounted on the upper surface of the package substrate 23. The controller 22 may be a semiconductor device controlling the plurality of memory devices 10 such as a central processing unit (CPU), a graphics processing unit (GPU), a system-on-chip (SoC), an application-specific integrated circuit (ASIC), a memory controller, and the like. The controller 22 may transmit, to the buffer die 21, a control signal for controlling each of the plurality of memory devices 10 and a data signal for storing data in at least a portion of the plurality of memory devices 10.

The buffer die 21 may transmit and receive signals to and from the controller 22 through the package substrate 23, and may buffer a signal received from the controller 22 to transmit the buffered signal to at least one of the plurality of memory devices 10 stacked thereon. The buffer die 21 may transmit and receive signals to and from the plurality of memory devices 10 through the plurality of via structures 18.

As described above, in each of the plurality of memory devices 10, the plurality of via structures 18 may be connected to elements in the element zone through the interconnection zone. Signals may be transmitted through the plurality of via structures 18, and thus a diode may be connected to at least one of the plurality of via structures 18 for the purpose of protecting the elements from electrostatic discharge (ESD) inflowing during processing and/or testing.

In an example embodiment of the disclosure, a diode may be disposed or provided in the keep-out zone around the plurality of via structures 18. As an example, at least one of impurity zones of the diode may be formed to have an area overlapping the keep-out zone. Accordingly, the area of the diode may be sufficiently increased to improve diode properties, thereby effectively preventing an issue such as element damage that may occur due to the inflow of ESD.

FIG. 2 is a schematic diagram illustrating a semiconductor package according to an example embodiment of the disclosure.

A semiconductor package 30 according to an example embodiment illustrated in FIG. 2 may be a high bandwidth memory (HBM)-type memory device having an increased bandwidth by including a plurality of channels having interfaces independent of each other. Referring to FIG. 2, the semiconductor package 30 may include a plurality of semiconductor devices 40 and 50 stacked on each other, and the plurality of semiconductor devices 40 and 50 include a buffer die 50 and a plurality of memory devices 40 (41 to 44). The plurality of memory devices 40 may be stacked on the buffer die 50, and may include first memory device 41, a second memory device 42, a third memory device 43, and a fourth memory device 44. However, the number of memory devices included in the plurality of memory devices 40 may vary in some example embodiments.

Each of the first memory device 41, the second memory device 42, the third memory device 43, and the fourth memory device 44, included in the plurality of memory devices 40, may include one or more channels. In the example embodiment illustrated in FIG. 2, each of the memory devices 41 to 44 may include two channels, and one memory device 40 may include eight channels CH1 to CH8. As an example, the first memory device 41 may include a first channel CH1 and a third channel CH3, and the second memory device 42 may include a second channel CH2 and a fourth channel CH4. The third memory device 43 may include a fifth channel CH5 and a seventh channel CH7, and the fourth memory device 44 may include a sixth channel CH6 and an eighth channel CH8.

The buffer die 50 may communicate with an external host such as a memory controller, an application processor, and a CPU, and may receive, from the external host, a command signal, an address signal, and a data signal. The buffer die 50 may provide the received command signal, address signal, and data signal to the memory devices 41 to 44. The buffer die 50 may be mounted on a package substrate included in the semiconductor package 30 and may exchange signals with the external host through a bump and an interconnection pattern in the package substrate. The buffer die 50 may buffer the command signal, address signal, and data signal, such that the external host may transmit and receive signals to and from the memory devices 41 to 44 while driving only a load of the buffer die 50.

The buffer die 50 and the memory devices 41 to 44 may be electrically connected to each other through a plurality of via structures 60. As an example, each of the plurality of via structures 60 may be a through-silicon via, passing through a silicon substrate.

The plurality of via structures 60 may be disposed or provided to correspond to the plurality of channels CH1 to CH8. The plurality of via structures 60 may be disposed or provided to pass through the first memory device 41, the second memory device 42, the third memory device 43, and the fourth memory device 44, and each of the first memory device 41, the second memory device 42, the third memory device 43, and the fourth memory device 44 may include an input/output circuit connected to the plurality of via structures 60. As an example, in an operation mode in which data input/output is independently performed for each channel, only one input/output circuit of the first memory device 41, the second memory device 42, the third memory device 43, and the fourth memory device 44 may be activated for each of the plurality of via structures 60.

Each of the plurality of via structures 60 may have a keep-out zone. The keep-out zone may be a zone surrounding each of the plurality of via structures 60, and elements involved in an actual operation may not be disposed or provided in the keep-out zone. Accordingly, a keep-out zone may be disposed or provided between an element zone in which the elements are disposed or provided and the plurality of via structures 60.

Each of the plurality of memory devices 41 to 44 may include a diode disposed or provided in the keep-out zone around the plurality of via structures 60, and the diode may be provided for the purpose of protecting the elements from ESD. As an example, the plurality of via structures 60 may be connected to the elements in the element zone through the diode, respectively. In an example embodiment of the disclosure, at least a portion of the diode may be disposed or provided in the keep-out zone, and thus, a maximum area of the diode may be secured to improve ESD properties of the diode and safely protect the elements from ESD.

Referring to FIG. 2, the buffer die 50 may include an internal command generator 51, a via zone 52, a physical (PHY) zone 53, a direct access (DA) zone 54, an interface circuit 55, and the like. The internal command generator 51 may generate an internal command using a command signal CMD received from the external host or the like.

The via zone 52 may be a zone in which the plurality of via structures 60 for communication with the memory devices 41 to 44 are formed. The physical zone 53 may be a zone in which an input/output circuit for communication with the external host or the like is disposed or provided. As an example, a signal, received from the external host, may be transmitted to the via zone 52 through the physical zone 53, and may be transmitted to at least one of the plurality of memory devices 40 through the plurality of via structures 60.

The direct access zone 54 may directly communicate with an external test device through a pad exposed to an outside of the semiconductor package 30 in a test mode for the semiconductor package 30. Signals, provided from the test device, may be provided to the plurality of memory devices 40 through the direct access zone 54 and the via zone 52.

The interface circuit 55 may provide an address signal and a data signal provided from the external host to at least one target memory device, among the first memory device 41, the second memory device 42, the third memory device 43, and the fourth memory device 44, and may output a data signal, output by the target memory device, to the external host. In addition, the interface circuit 55 may provide, to the external device, a determination signal related to a test provided from the target memory device.

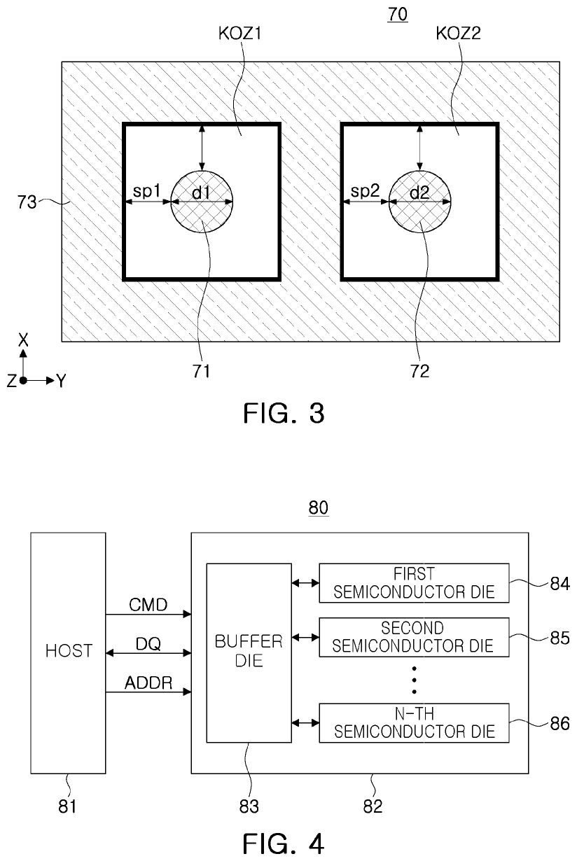

FIG. 3 is a diagram illustrating an arrangement relationship between via structures according to an example embodiment of the disclosure.

In an example embodiment, a semiconductor device 70 may include a first via structure 71, a second via structure 72, a first keep-out zone KOZ1, a second keep-out zone KOZ2, and an element zone 73. The first keep-out zone KOZ1 and the second keep-out zone KOZ2 may be zones in which elements are not formed in consideration of thermal stress of the first via structure 71 and the second via structure 72. Accordingly, as illustrated in FIG. 3, the first keep-out zone KOZ1 may be provided between the element zone 73 and the first via structure 71, and the second keep-out zone KOZ2 may be provided between the element zone 73 and the second via structure 72.

The first via structure 71 may have a first diameter d1, and the second via structure 72 may have a second diameter d2. The first diameter d1 and the second diameter d2 may be the same or different.

A boundary of the first keep-out zone KOZ1 may be isolated from the first via structure 71 by a first distance sp1. A boundary of the second keep-out zone KOZ2 may be isolated from the second via structure 72 by a second distance sp2. The first distance sp1 and the second distance sp2 may be the same or different. In addition, each of the first keep-out zone KOZ1 and the second keep-out zone KOZ2 may have a square shape.

FIG. 4 is a schematic diagram illustrating a system including a semiconductor package according to an example embodiment of the disclosure.

Referring to FIG. 4, a system 80 according to an example embodiment may include a semiconductor package 82 and a host 81. The semiconductor package 80 may include a plurality of semiconductor dies 84 to 86 and a buffer die 83. The buffer die 83 may be mounted on a package substrate, and the plurality of semiconductor dies 84 to 86 may be stacked on the buffer die 83. Each of the plurality of semiconductor dies 84 to 86 may be a memory device for storing data. In some example embodiments, the host 81 may be mounted on a package substrate such as the buffer die 83.

The host 81 may provide, to the semiconductor package 82, a command signal CMD and an address signal ADDR necessary for an operation of the semiconductor package 82. As described above with reference to FIG. 2, the buffer die 83 may buffer the command signal CMD and the address signal ADDR and transmit the buffered signals to at least one of the plurality of semiconductor dies 84 to 86. Each of the semiconductor dies 84 to 86 may perform a control operation such as a read operation, write operation, erase operation, or refresh operation in response to the command signal CMD and address signal ADDR received through the buffer die 83. The host 81 may receive, from the semiconductor package 82, a data signal DQ output as a result of the control operation performed by each of the plurality of semiconductor dies 84 to 86, or may transmit, to the semiconductor package 82, the data signal DQ including data to be stored.

The plurality of semiconductor dies 84 to 86 may be stacked on the buffer die 83, and a portion of the plurality of semiconductor dies 84 to 86 may form a single semiconductor layer. A plurality of semiconductor dies 41 to 44 and the buffer die 83 may be electrically connected to each other through a plurality of via structures. As an example, each of the plurality of via structures may be a through-silicon via, passing through a silicon substrate.

Each of the plurality of via structures may have a keep-out zone. The keep-out zone may be a zone surrounding each of the plurality of via structures, and elements involved in an actual operation may not be disposed or provided in the keep-out zone. Accordingly, a keep-out zone may be disposed or provided between an element zone in which the elements are disposed or provided and the plurality of via structures.

Each of the plurality of semiconductor dies 84 to 86 may include a first diode and a second diode. At least one of the first and second diodes may be disposed or provided to have an area overlapping the keep-out zone of each of the via structures. The first diode and the second diode may be provided for the purpose of protecting the elements from ESD inflowing during processing and/or testing. In an example embodiment, a via structure may be disposed or provided between the first diode and the second diode.

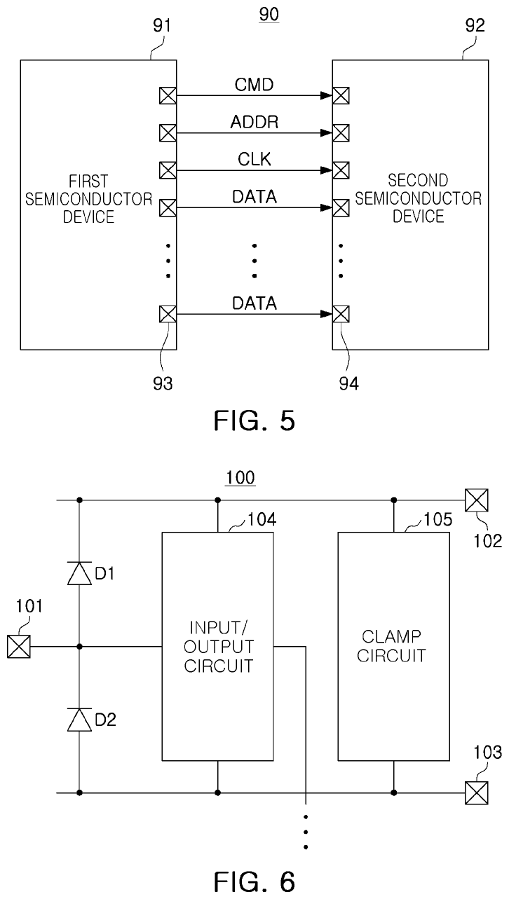

FIG. 5 is a schematic diagram illustrating a system including semiconductor devices according to an example embodiment of the disclosure.

Referring to FIG. 5, a system 90 according to an example embodiment may include a first semiconductor device 91 and a second semiconductor device 92. The first semiconductor device 91 and the second semiconductor device 92 may operate while exchanging signals with each other. In the example embodiment illustrated in FIG. 5, the first semiconductor device 91 may operate as a memory controller, and the second semiconductor device 92 may operate as a memory device storing data. As an example, the first semiconductor device 91 and the second semiconductor device 92 may exchange signals with each other through via structures, passing through a semiconductor substrate.

The first semiconductor device 91 may include a plurality of first pads 93. The second semiconductor device 92 may include a plurality of second pads 94. The plurality of first pads 93 and the plurality of second pads 94 may be electrically connected to each other to provide a signal transmission path. As an example, the first semiconductor device 91 may transmit, to the second semiconductor device 92, a command signal CMD, an address signal ADDR, a clock signal CLK, or the like.

The second semiconductor device 92 may operate in response to the command signal CMD, the address signal ADDR, the clock signal CLK, or the like. The second semiconductor device 92 may store data stored in a data signal DATA received from the first semiconductor device 91, or may read the stored data and transmit the generated data signal DATA to the first semiconductor device 91.

The plurality of first pads 93 and the plurality of second pads 94 may be externally exposed and may be connected to an interconnection pattern or a wire of a package substrate included in the system 91. As an example, in a state in which the plurality of second pads 94 are externally exposed, when static electricity is generated in surroundings thereof, a large amount of current may flow to at least one of the plurality of second pads 94. When the current flows into an internal circuit of the second semiconductor device 94, the second semiconductor device 94 may be damaged.

In order to prevent an issue caused by the large amount of current, a first diode and a second diode may be connected to at least one of the plurality of second pads 94. Each of the first diode and the second diode may be connected to at least one of the plurality of second pads 94 through a metal interconnection formed of a conductive material such as metal or the like.

The first diode and the second diode may be connected to each other, thereby providing a discharge path for the current flowing into the plurality of second pads 94, and preventing damage to elements, included in the second semiconductor device 92, therefrom. The first diode and the second diode may be formed to have high current driving force.

In addition, in order to have high current driving force, at least one of the first diode and the second diode may be disposed or provided in a keep-out zone of each of the via structures connected to the plurality of second pads 94. The first diode and/or the second diode may be disposed or provided in the keep-out zone, thereby increasing an area of the first diode and/or the second diode and increasing current driving force to improve ESD properties.

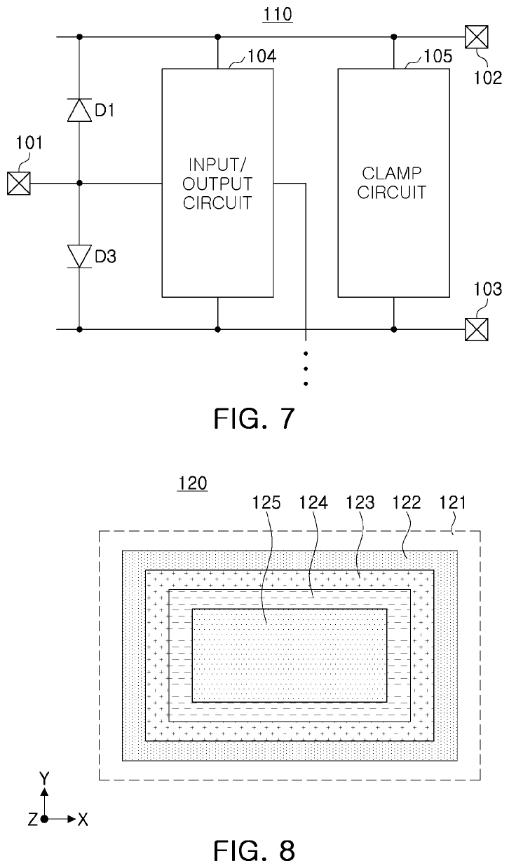

FIGS. 6 and 7 are schematic diagrams illustrating a semiconductor device according to an example embodiment of the disclosure.

First, referring to FIG. 6, a semiconductor device 100 according to an example embodiment may include a signal pad 101, a first power pad 102, a second power pad 103, an input/output circuit 104, a clamp circuit 105, and the like. As an example, the first power pad 102 may be a pad to which a power supply voltage is input, and the second power pad 103 may be a pad to which a reference voltage lower than the power supply voltage is input.

The input/output circuit 104 may be connected to the signal pad 101, and may transmit an output signal to the signal pad 101 or receive an input signal through the signal pad 101. As an example, a portion of elements, included in the input/output circuit 104, may receive a first power voltage from the first power pad 102, and the other portion may receive a second power voltage from the second power pad 103.

The semiconductor device 100 may include a first diode D1 connected between the signal pad 101 and the first power pad 102, and a second diode D2 connected between the signal pad 101 and the second power pad 103. The first diode D1 may include the first impurity zone and the second impurity zone, and the second diode D2 may include the third impurity zone and the fourth impurity zone. As an example, at least one of the first diode D1 and the second diode D2 may be disposed or provided in a zone between the input/output circuit 104 and a via structure.

In an example embodiment, the first impurity zone of the first diode D1 may be doped with an N-type impurity and connected to the first power pad 102 through a cathode, and the second impurity zone of the first diode D1 may be doped with a P-type impurity and connected to the signal pad 101 through an anode. The third impurity zone of the second diode D2 may be doped with a P-type impurity and connected to the second power pad 103 through an anode, and the fourth impurity zone of the second diode D2 may be doped with an N-type impurity and connected to the signal pad 101 through a cathode.

When high current is applied to the signal pad 101 due to processing or testing, the current may flow to the second power pad 103 through the first diode D1 and the clamp circuit 105 in an ideal case. Accordingly, the high current may not flow into the input/output circuit 104 involved in an actual operation of the semiconductor device 100, and the semiconductor device 100 may be effectively protected.

Referring to FIG. 7, a semiconductor device 110 may be the same as the semiconductor device 100 of FIG. 6, except that a second diode D2 is replaced with a third diode D3. In FIG. 7, reference numerals the same as those in FIG. 6 denote the same members. In FIG. 7, contents described with reference to FIG. 6 are briefly described or omitted.

The semiconductor device 110 may include a first diode D1 connected between a signal pad 101 and a first power pad 102, and a third diode D3 connected between the signal pad 101 and a second power pad 103. A first impurity zone of the first diode D1 may be doped with an N-type impurity and connected to the first power pad 102 through a cathode, and a second impurity zone of the first diode D1 may be doped with a P-type impurity and connected to the signal pad 101 through an anode. In an example embodiment, a third impurity zone of the third diode D3 may be doped with an N-type impurity and connected to the second power pad 103 through an anode, and a fourth impurity zone of the third diode D3 may be doped with a P-type impurity and connected to the signal pad 101 through a cathode.

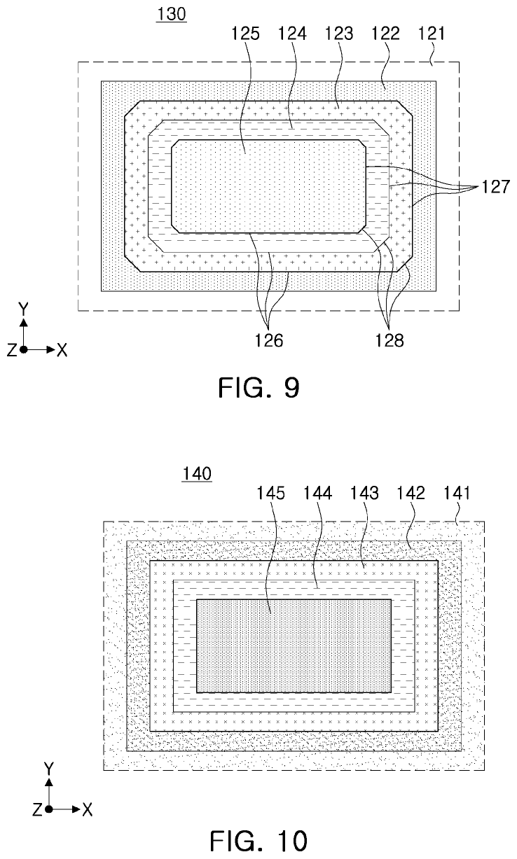

FIGS. 8 and 9 are schematic diagrams illustrating a first diode included in a semiconductor device according to an example embodiment of the disclosure.

FIG. 8 may be a plan view illustrating a first diode 120 according to an example embodiment of the disclosure. Referring to FIG. 8, the first diode 120 according to an example embodiment may include a first impurity zone 123 and a second impurity zone 125 formed on a semiconductor substrate 121. Each of the first impurity zone 123 and the second impurity zone 125 may be formed in a first well zone 122 of the semiconductor substrate 121.

The first impurity zone 123 may be doped with a first conductivity-type impurity, and the second impurity zone 125 may be doped with a second conductivity-type impurity, different from the first conductivity-type impurity. In an example embodiment, the first impurity zone 123 may be doped with an N-type impurity and the second impurity zone 125 may be doped with a P-type impurity. The first well zone 122 may be a deep N-well zone doped with an N-type impurity the same as that of the first impurity zone 123. A doping concentration of the first well zone 122 may be lower than that of the first impurity zone 123.

A first element isolation film 124 may be disposed or provided between the first impurity zone 123 and the second impurity zone 125. The first impurity zone 123 may be formed to surround the second impurity zone 125 in directions, parallel to an upper surface of the semiconductor substrate 121 with the first element isolation film 124 interposed therebetween, As an example, a first direction (X-axis direction in FIG. 8) and a second direction (Y-axis direction in FIG. 8) orthogonal to the first direction. The first element isolation film 124 may be formed of an insulating material such as silicon oxide or silicon nitride.

FIG. 9 may be a plan view illustrating a first diode according to an example embodiment of the disclosure. Specifically, a first diode 130 may be the same as the first diode 120 of FIG. 8, except for a shape of the first diode 130. In FIG. 9, reference numerals the same as those in FIG. 8 denote the same members. In FIG. 9, contents described in FIG. 8 are briefly described or omitted.

Each of a first impurity zone 123 and a second impurity zone 125 may have a first boundary 126 extending in a first direction (X-axis direction in FIG. 9), parallel to an upper surface of a semiconductor substrate 121, and a second boundary 127 extending in a second direction (Y-axis direction in FIG. 9), parallel to the upper surface of the substrate 121 and orthogonal to the first direction. At least one of the first impurity zone 123 and the second impurity zone 125 may have a third boundary 128 extending in a third direction, intersecting the first and second directions.

Current driving force of a diode may be proportional to a circumference of the first impurity zone 123 or a circumference of the second impurity zone 125. The circumference of the first impurity zone 123 or the circumference of the second impurity zone 125 may be increased by allowing the first diode 130 to include the third boundary 128. Accordingly, the first diode 130 may have increased current driving force.

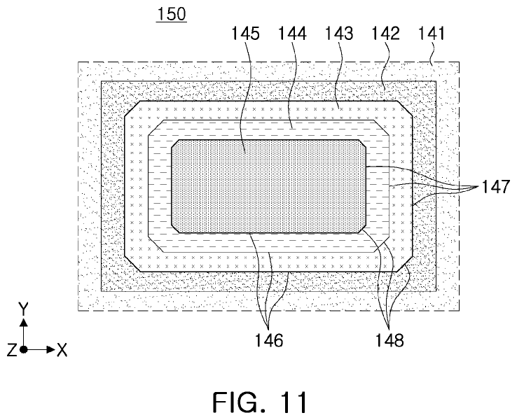

FIGS. 10 and 11 are schematic diagrams illustrating a second diode included in a semiconductor device according to an example embodiment of the disclosure.

FIG. 10 may be a plan view illustrating a second diode 140 according to an example embodiment of the disclosure. Referring to FIG. 10, the second diode 140 according to an example embodiment may include a third impurity zone 143 and a fourth impurity zone 145 formed on a semiconductor substrate. Each of the third impurity zone 143 and the fourth impurity zone 145 may be formed in a second well zone 142 of the semiconductor substrate.

The third impurity zone 143 may be doped with a first conductivity-type impurity, and the fourth impurity zone 145 may be doped with a second conductivity-type impurity, different from the first conductivity-type impurity. In an example embodiment, the third impurity zone 143 may be doped with a P-type impurity and the fourth impurity zone 145 may be doped with an N-type impurity. The second well zone 142 may be a pocket P-well, and an N-well may be present around the second well zone 142.

A detailed structure of the second diode 140 may be the same as that of the first diode 120 of the example embodiment described with reference to FIG. 8. Accordingly, the description of FIG. 8 is omitted.

FIG. 11 may be a plan view illustrating a second diode according to an example embodiment of the disclosure. Specifically, a second diode 150 may be the same as the second diode 140 of FIG. 10, except for a shape of the second diode 150. In FIG. 11, reference numerals the same as those in FIG. 10 denote the same members. In FIG. 11, contents described in FIG. 10 are briefly described or omitted.

Each of a third impurity zone 143 and a fourth impurity zone 145 may have a first boundary 146 extending in a first direction (X-axis direction in FIG. 11), parallel to an upper surface of a semiconductor substrate 141, and a second boundary 147 extending in a second direction (Y-axis direction in FIG. 11), parallel to the upper surface of the substrate 141 and orthogonal to the first direction. At least one of the third impurity zone 143 and the fourth impurity zone 145 may have a third boundary 148 extending in a third direction, intersecting the first and second directions.

Current driving force of a diode may be proportional to a circumference of the third impurity zone 143 or a circumference of the fourth impurity zone 145. The circumference of third impurity zone 143 or the circumference of the fourth impurity zone 145 may be increased by allowing the second diode 150 to include the third boundary 148. Accordingly, the second diode 150 may have increased current driving force.

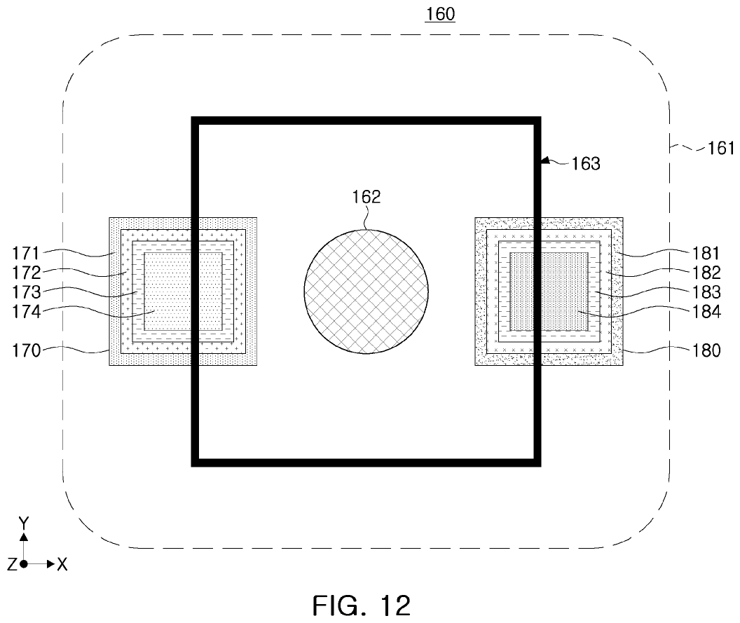

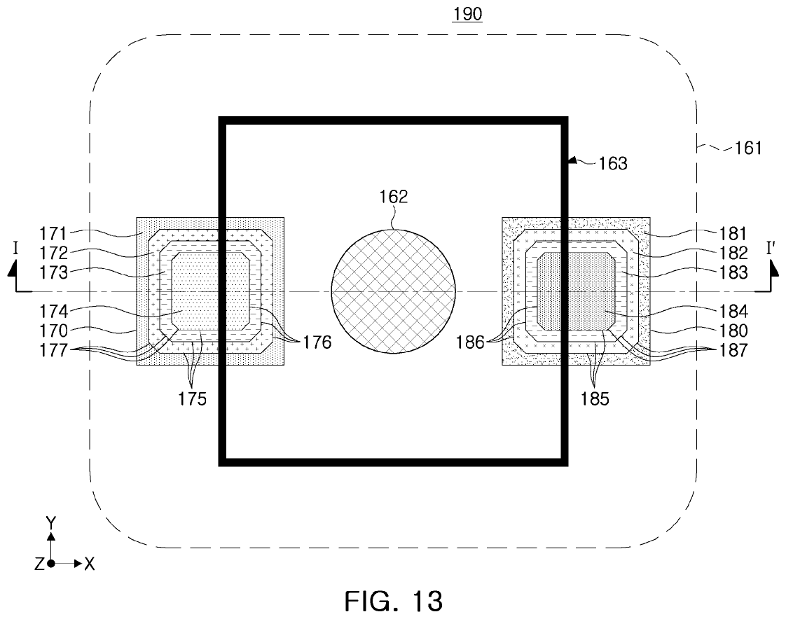

FIGS. 12 and 13 are diagrams illustrating a semiconductor device according to an example embodiment of the disclosure.

FIG. 12 may be a diagram illustrating a semiconductor device 160 viewed from above an upper surface of the semiconductor device 160. The semiconductor device 160 may include a semiconductor substrate 161, a via structure 162, a keep-out zone 163, a first diode 170, and a second diode 180.

The first diode 170 according to an example embodiment may include a first impurity zone 172 and a second impurity zone 174 formed on the semiconductor substrate 161. Each of the first impurity zone 172 and the second impurity zone 174 may be formed in a first well zone 171 of the semiconductor substrate 161. The first impurity zone 172 may be doped with a first conductivity-type impurity, and the second impurity zone 174 may be doped with a second conductivity-type impurity, different from the first conductivity-type impurity. In an example embodiment, the first impurity zone 172 may be doped with an N-type impurity and the second impurity zone 174 may be doped with a P-type impurity. A first element isolation film 173 may be disposed or provided between the first impurity zone 172 and the second impurity zone 174.

The second diode 180 according to an example embodiment may include a third impurity zone 182 and a fourth impurity zone 184 formed on the semiconductor substrate 161. Each of the third impurity zone 182 and the fourth impurity zone 184 may be formed in a second well zone 181 of the semiconductor substrate 161. The third impurity zone 182 may be doped with a first conductivity-type impurity, and the fourth impurity zone 184 may be doped with a second conductivity-type impurity, different from the first conductivity-type impurity. In an example embodiment, the third impurity zone 182 may be doped with an N-type impurity and the fourth impurity zone 184 may be doped with a P-type impurity. A second element isolation film 183 may be disposed or provided between the third impurity zone 182 and the fourth impurity zone 184.

The via structure 162 may be a structure, passing through the semiconductor substrate 161. The via structure 162 may be a through-silicon via extending from an interconnection pattern formed in an interconnection zone defined on the semiconductor substrate 161 in a direction (Z-axis direction in FIG. 12), perpendicular to an upper surface of the semiconductor substrate 161.

The keep-out zone 163 according to an example embodiment of the disclosure may be a zone surrounding the via structure 162. In the example embodiment illustrated in FIG. 12, the keep-out zone 163 may have a square shape. Elements may not be formed in the keep-out zone 163, and the elements may be formed around the keep-out zone 163.

In the example embodiment illustrated in FIG. 12, the via structure 162 may be disposed or provided between the first diode 170 and the second diode 180 in a first direction that is parallel to the upper surface of the semiconductor substrate 161.

FIG. 13 may be a diagram illustrating a semiconductor device 190 viewed from above an upper surface of the semiconductor device 190. Specifically, the semiconductor device 190 may be the same as the semiconductor device 160 of FIG. 12, except for shapes of a first diode 170 and a second diode 180. In FIG. 13, reference numerals the same as those in FIG. 12 denote the same members. In FIG. 13, contents described in FIG. 12 are briefly described or omitted.

The first diode 170 according to the example embodiment illustrated in FIG. 13 may have a third boundary 177. Each of a first impurity zone 172 and a second impurity zone 174 may have a first boundary 175 extending in a first direction (X-axis direction in FIG. 13), parallel to an upper surface of a semiconductor substrate 161, and a second boundary 176 extending in a second direction (Y-axis direction in FIG. 13), parallel to the upper surface of the semiconductor substrate 161 and orthogonal to the first direction.

The second diode 180 according to the example embodiment illustrated in FIG. 13 may have a third boundary 187. Each of a third impurity zone 182 and a fourth impurity zone 184 may have a first boundary 185 extending in a first direction that is parallel to the upper surface of the semiconductor substrate 161, and a second boundary 186 extending in a second direction that is parallel to the upper surface of the semiconductor substrate 161 and orthogonal to the first direction.

At least one of the first impurity zone 172, the second impurity zone 174, the third impurity zone 182, and the fourth impurity zone 184 according to an example embodiment may have third boundaries 177 and 187 extending in a third direction, intersecting the first and second directions.

In the example embodiments illustrated in FIGS. 12 and 13, at least one of the first impurity zone 172, the second impurity zone 174, the third impurity zone 182, and the fourth impurity zone 184 may have a zone overlapping (or overlap with) the keep-out zone 163. In addition, each of the first diode 170 and the second diode 180 may have a square shape having the same length in the first direction and the second direction. As an example, referring to FIGS. 12 and 13, in the second direction, lengths of the first diode 220 and the second diode 230 may be shorter than a length of the keep-out zone 163.

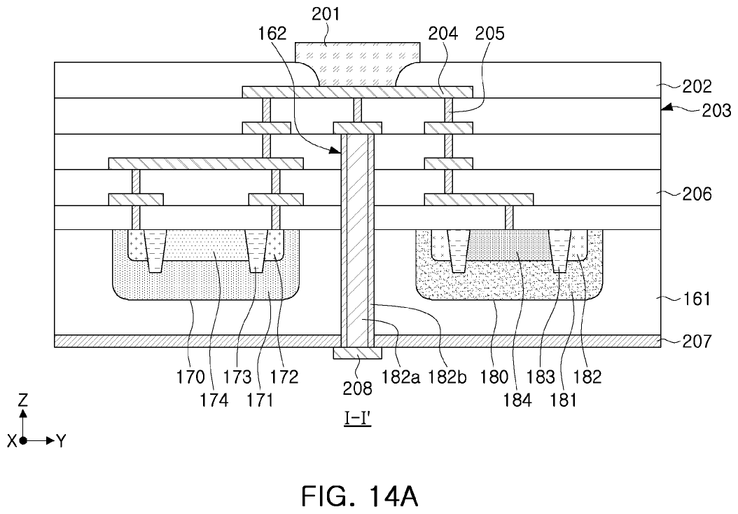

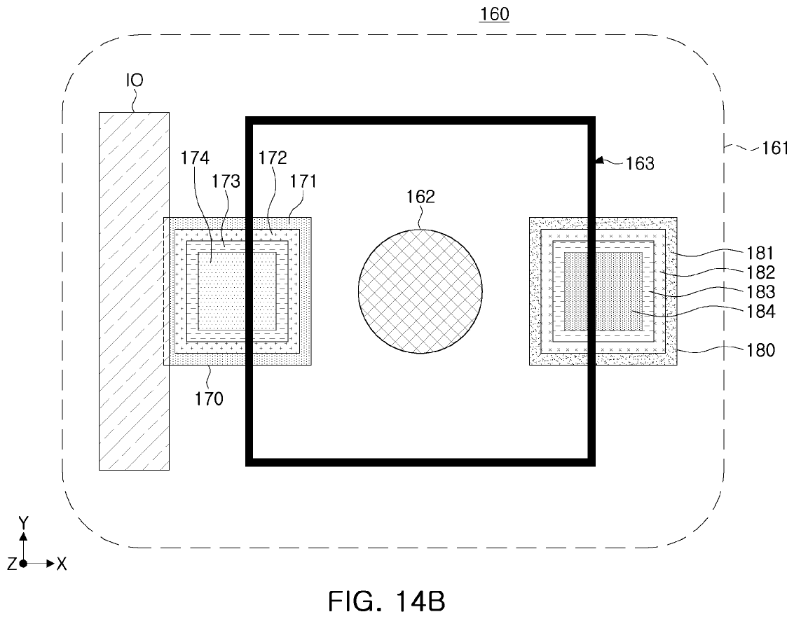

FIG. 14A is a cross-sectional view of the semiconductor device illustrated in FIG. 13 taken along line I-I′ according to an example embodiment of the disclosure.

Referring to FIG. 1. 14A, a passivation layer 202 may be formed on an upper portion of the semiconductor device 190, and a portion of a redistribution pattern 204 may be externally exposed and may be connected to an upper pad 201 in a zone in which the passivation layer 202 is removed. The redistribution layer 203 may include a redistribution pattern 204 and an upper contact 205, and the redistribution pattern 204 may be connected to the redistribution pattern 204 and a via structure 162 through the upper contact 205.

The via structure 162 may be connected to semiconductor elements formed on the semiconductor substrate 161 through the redistribution pattern 204 disposed or provided in a plurality of interlayer insulating layers 206. As an example, the semiconductor elements, connected to the via structure 162, may be a first diode 170 and a second diode 180, providing a path through which overcurrent inflowing due to ESD is flowable. The via structure 162 may be divided into a via electrode 162a and a via insulating layer 162b.

The semiconductor device 190 may include a lower pad 208. The lower pad 208 may be electrically connected to the via structure 162, passing through the semiconductor substrate 161. The lower pad 208 may be insulated from the semiconductor substrate 161 by a lower protective insulating layer 207 of the semiconductor substrate 161. The lower protective insulating layer 207 may be formed of silicon oxide or silicon nitride.

Overcurrent, flowing into the upper pad 201 and/or the lower pad 108 due to externally generated ESD, may flow to the first diode 170 or the second diode 180 through the via structure 162. The overcurrent flowing into the first diode 170 and the second diode 180 may be discharged, through a clamp circuit, to a power pad to which a power voltage is applied, thereby preventing overcurrent from flowing to elements involved in an operation of the semiconductor device 190.

FIG. 14B is a diagram illustrating a connection relationship with an input/output circuit of the semiconductor device illustrated in FIG. 12 according to an example embodiment of the disclosure.

A first diode 170 according to an example embodiment may include a first impurity zone 172 and a second impurity zone 174 formed on a semiconductor substrate 161. Each of the first impurity zone 172 and the second impurity zone 174 may be formed in a first well zone 171 of the semiconductor substrate 161. In an example embodiment, the first well zone 171 may be doped with an N-type impurity, and at least a portion of the first well zone 171 may have a zone overlapping (or overlap with) an N well zone of an input/output circuit zone IO.

A shape of the first diode according to an example embodiment may be the same as or different from that of the second diode. The first well zone 171 may have various shapes, and the number of transistors disposed or provided in the input/output circuit zone IO may be at least one.

The first well zone 171 of the first diode 170 may have a zone overlapping (or overlap with) the N well zone of the input/output circuit zone IO, thereby effectively securing a space on the semiconductor substrate 161. In addition, a degree of freedom in disposing elements in the input/output circuit zone IO may be increased, and a degree of integration of a semiconductor device 160 may be improved.

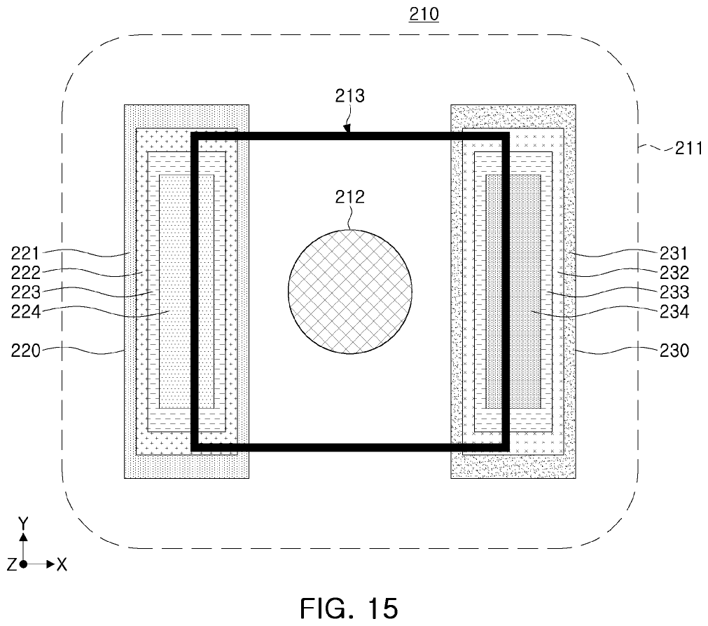

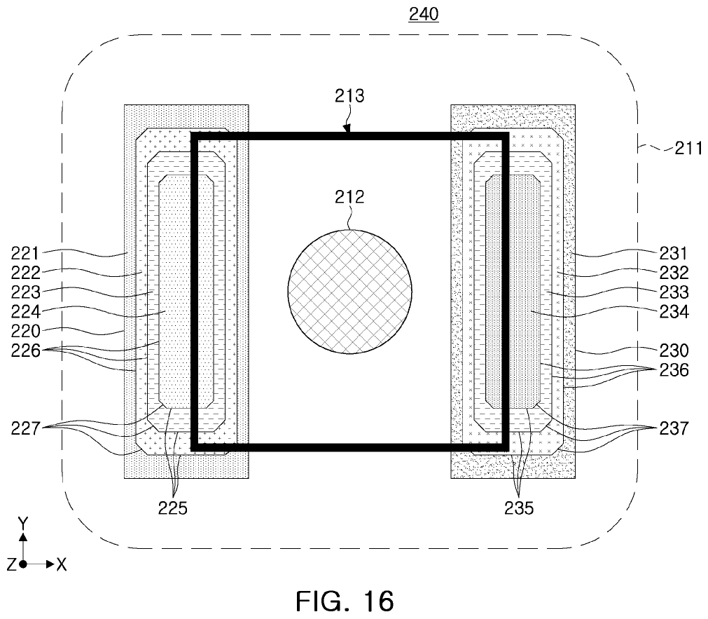

FIGS. 15 and 16 are diagrams illustrating a semiconductor device according to an example embodiment of the disclosure.

FIG. 15 may be a diagram illustrating a semiconductor device 210 viewed from above an upper surface of the semiconductor device 210. The semiconductor device 210 may include a semiconductor substrate 211, a via structure 212, a keep-out zone 213, a first diode 220, and a second diode 230.

In a similar manner to other example embodiments described above, the via structure 212 may be a through-silicon via, passing through the semiconductor substrate 211. The keep-out zone 213 may be defined around the via structure 212, and may be a zone in no elements are formed in consideration of thermal stress of the via structure 212. Accordingly, elements involved in an operation of the semiconductor device 210 may be disposed or provided on an outside of the keep-out zone 213.

The first diode 220 and the second diode 230 may be connected to the via structure 212 to provide a current path through which overcurrent, externally inflowing due to ESD, is flowable. As an example, the first diode 220 may be connected between a first power pad, supplying a first power voltage, and the via structure 212, and the second diode 230 may be connected between a second power pad, supplying a second power voltage different from the first power voltage, and the via structure 212.

A configuration of each of the first diode 220 and the second diode 230 may be similar to that described above with reference to FIG. 12. As an example, referring to FIG. 15, the first diode 220, formed in a first well zone 221, may include a first impurity zone 222, a second impurity zone 224, and a first element isolation film 223 disposed or provided therebetween. The second diode 230 may include a third impurity zone 232, a fourth impurity zone 234, and a second element isolation film 233 disposed or provided therebetween, formed in a second well zone 231. In the example embodiment illustrated in FIG. 16, the impurity zones 222, 224, 232, and 234 may include third boundaries 227 and 237, intersecting a first direction (X-axis direction) and a second direction (Y-axis direction) and extending in a direction that is parallel to an upper surface of the semiconductor substrate 211.

In the example embodiments illustrated in FIGS. 15 and 16, at least one of the impurity zones 222, 224, 232, and 234, providing the first diode 220 and the second diode 230, may be formed to overlap the keep-out zone 213. In addition, each of the first diode 220 and the second diode 230 may have a rectangular shape extending longer in the second direction than in the first direction. As an example, referring to FIGS. 15 and 16, in the second direction, the first diode 220 and the second diode 230 may have lengths longer than that of the keep-out zone 213.

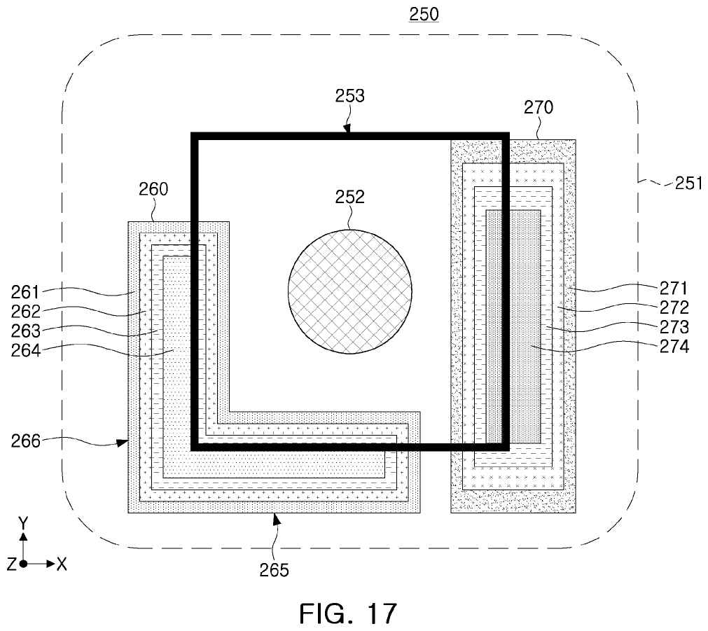

FIGS. 17 to 20 are diagrams illustrating a semiconductor device according to an example embodiment of the disclosure.

FIGS. 17 to 20 may be diagrams illustrating semiconductor devices 250, 280, 290, and 300 viewed from above upper surfaces of the semiconductor devices 250, 280, 290, and 300. The semiconductor devices 250, 280, 290, and 300 may include a semiconductor substrate 251, a via structure 252, a keep-out zone 253, a first diode 260, and a second diode 270.

In a similar manner to other example embodiments described above, the via structure 252 may be a through-silicon via, passing through the semiconductor substrate 251. The keep-out zone 253 may be defined around the via structure 252, and may be a zone in no elements are formed in consideration of thermal stress of the via structure 252. Accordingly, elements involved in operations of the semiconductor devices 250, 280, 290, and 300 may be disposed or provided on an outside of the keep-out zone 253.

The first diode 260 and the second diode 270 may be connected to the via structure 252 to provide a current path through which overcurrent, externally inflowing due to ESD, is flowable. As an example, the first diode 260 may be connected between a first power pad, supplying a first power voltage, and the via structure 252, and the second diode 270 may be connected between a second power pad, supplying a second power voltage different from the first power voltage, and the via structure 252.

A configuration of each of the first diode 260 and the second diode 270 may be similar to that described above with reference to FIG. 12.

As an example, referring to FIG. 17, the first diode 260, formed in a first well zone 261, may include a first impurity zone 262, a second impurity zone 264, and a first element isolation film 263 disposed or provided therebetween. The second diode 270 may include a third impurity zone 272, a fourth impurity zone 274, and a second element isolation film 273 disposed or provided therebetween, formed in a second well zone 271.

The first diode 260 according to an example embodiment of the disclosure may include a first zone 265 extending in a first direction (X-axis direction in FIG. 17), parallel to an upper surface of the semiconductor substrate 251, and a second zone 266 extending in a second direction (Y-axis direction in FIG. 17), parallel to the upper surface of the semiconductor substrate 251 and orthogonal to the first direction. The second diode 270 may extend in the second direction. That is, a shape of the first diode 260 may be different from that of the second diode 270. A via structure 252 may be disposed or provided between the first diode 260 and the second diode 270 in the first direction of the semiconductor substrate 251. In other words, the via structure 252 may be disposed or provided between the second zone 266 and the second diode 270 in the first direction. The first zone 265 and the via structure 252 may be disposed or provided to be parallel to each other in the second direction.

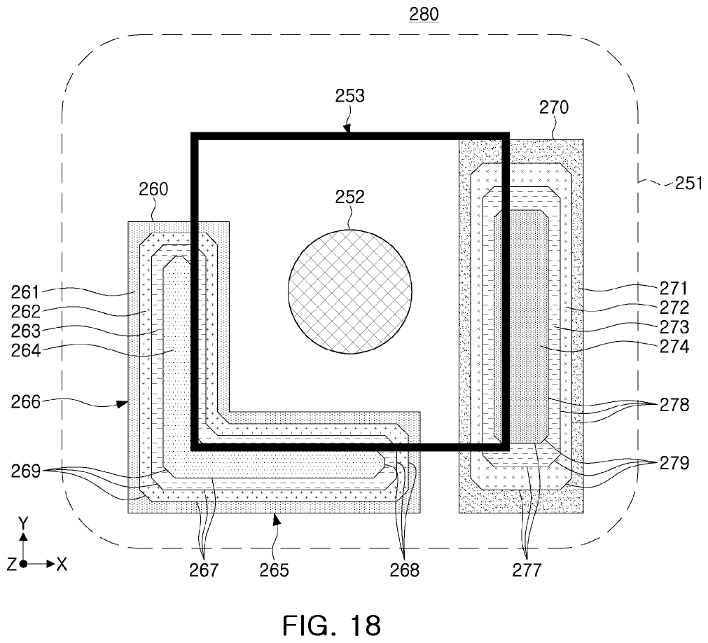

In the example embodiment illustrated in FIG. 18, a semiconductor device 280 may be the same as the semiconductor device 250 of FIG. 17, except for shapes of a first diode 260 and a second diode 270. Impurity zones 262, 264, 272, and 274 may include third boundaries 269 and 279, intersecting a first direction (X-axis direction) and a second direction (Y-axis direction) and extending in a direction that is parallel to an upper surface of a semiconductor substrate 211.

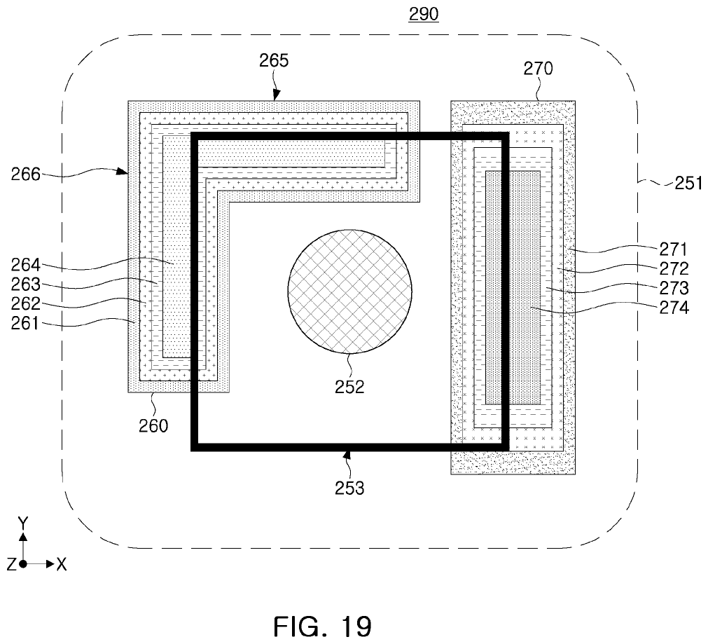

In the example embodiment illustrated in FIG. 19, specifically, a semiconductor device 290 may be the same as the semiconductor device 250 of FIG. 17, except for a position of a first zone 265 being changed. A via structure 252 may be disposed or provided between a first diode 260 and a second diode 270 in a first direction of a semiconductor substrate 251. In other words, the first diode 260 may include a first zone 265 extending in a first direction, and a second zone 266 extending in a second direction that is parallel to an upper surface of the semiconductor substrate 251 and orthogonal to the first direction. The via structure 252 may be disposed or provided between the second zone 266 and the second diode 270 in the first direction. The first zone 265 and the via structure 252 may be disposed or provided to be parallel to each other in the second direction.

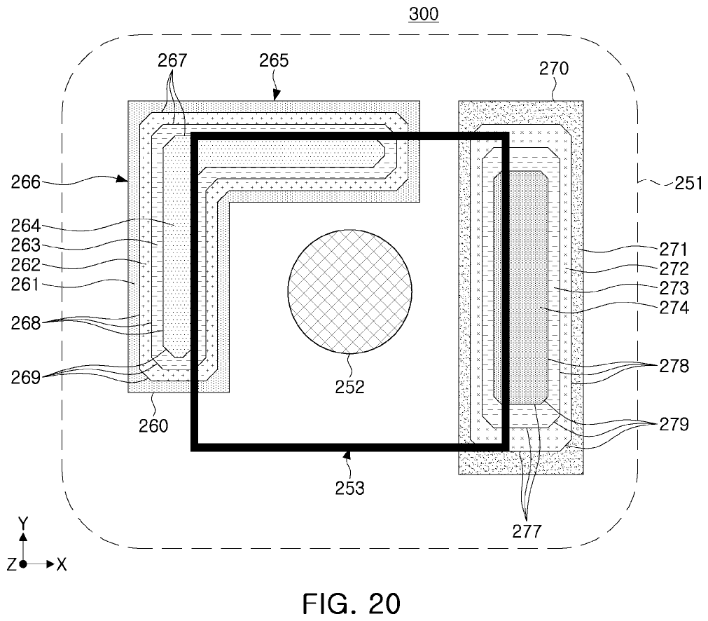

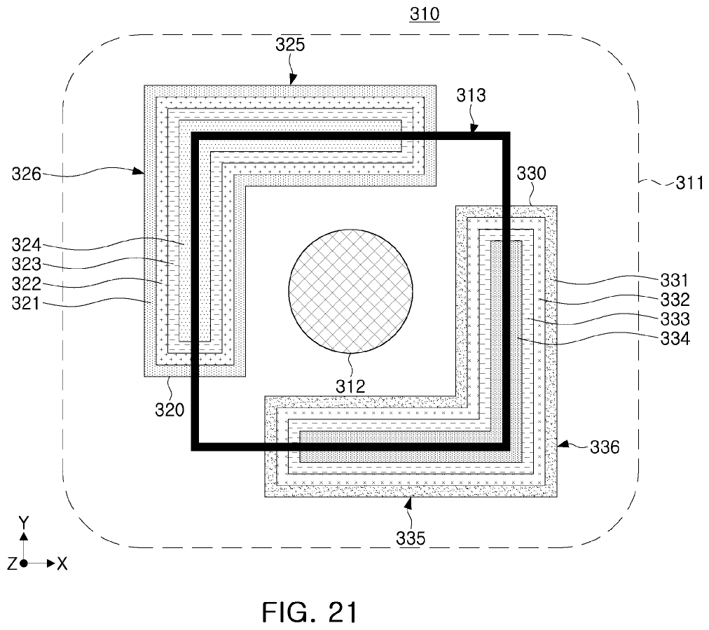

In the example embodiment illustrated in FIG. 20, a semiconductor device 300 may be the same as the semiconductor device 290 of FIG. 19, except for shapes of a first diode 260 and a second diode 270. Impurity zones 262, 264, 272, and 274 may include third boundaries 269 and 279, intersecting a first direction (X-axis direction) and a second direction (Y-axis direction) and extending in a direction that is parallel to an upper surface of a semiconductor substrate 211.

In the example embodiments illustrated in FIGS. 17 to 20, at least one of the first diode 260 and the second diode 270 may have a zone overlapping (or overlap with) the keep-out zone 253. In other words, at least one of the impurity zones 262, 264, 272, and 274, providing the first diode 260 and the second diode 270, may overlap the keep-out zone 253.

Current driving force of a diode may be proportional to a circumference of an impurity zone. That is, in the example embodiments of FIGS. 17 to 20, the first diode 260 may be allowed to include the first zone 265 and the second zone 266, thereby increasing a circumference of the first impurity zone 262 and a circumference of the second impurity zone 264. In addition, a degree of freedom in design may be increased according to an arrangement of a first zone 267 of the first diode 260. The above-described example embodiments may suffer losses in terms of a degree of integration, but may effectively protect elements from ESD inflowing during processing and/or testing by increasing current driving force of the first diode 260.

FIGS. 21 to 24 are diagrams illustrating a semiconductor device according to an example embodiment of the disclosure.

FIGS. 21 to 24 are diagrams illustrating semiconductor devices 310, 340, 350, and 360 viewed from above upper surfaces of the semiconductor devices 310, 340, 350, and 360. The semiconductor devices 310, 340, 350, and 360 may include a semiconductor substrate 311, a via structure 312, a keep-out zone 313, a first diode 320, and a second diode 330.

In a similar manner to other example embodiments described above, the via structure 312 may be a through-silicon via, passing through the semiconductor substrate 311. The keep-out zone 313 may be defined around the via structure 312, and may be a zone in no elements are formed in consideration of thermal stress of the via structure 312. Accordingly, elements involved in operations of the semiconductor devices 310, 340, 350, and 360 may be disposed or provided on an outside of the keep-out zone 313.

The first diode 320 and the second diode 330 may be connected to the via structure 312 to provide a current path through which overcurrent, externally inflowing due to ESD, is flowable. As an example, the first diode 320 may be connected between a first power pad, supplying a first power voltage, and the via structure 312, and the second diode 330 may be connected between a second power pad, supplying a second power voltage different from the first power voltage, and the via structure 312.

A configuration of each of the first diode 320 and the second diode 330 may be similar to that described above with reference to FIG. 12.

As an example, referring to FIG. 21, the first diode 320, formed in a first well zone 321, may include a first impurity zone 322, a second impurity zone 324, and a first element isolation film 323 disposed or provided therebetween. The second diode 330 may include a third impurity zone 332, a fourth impurity zone 334, and a second element isolation film 333 disposed or provided therebetween, formed in a second well zone 331.

The first diode 320 according to an example embodiment of the disclosure may include a first zone 325 extending in a first direction (X-axis direction in FIG. 21), parallel to an upper surface of the semiconductor substrate 311, and a second zone 326 extending in a second direction (Y-axis direction in FIG. 21), parallel to the upper surface of the semiconductor substrate 311 and orthogonal to the first direction. The second diode 330 according to an example embodiment of the disclosure may include a third zone 335 extending in the first direction, and may include a fourth zone 336 extending in the second direction. That is, a shape of the first diode 320 may be different from that of the second diode 330.

As an example, the via structure 312 may be disposed or provided between the first diode 320 and the second diode 330 in a first direction of the semiconductor substrate 311. In other words, the via structure 312 may be disposed or provided between the second zone 326 and the fourth zone 336 in the first direction, and may be disposed or provided between the first zone 325 and the third zone 335 in the second direction.

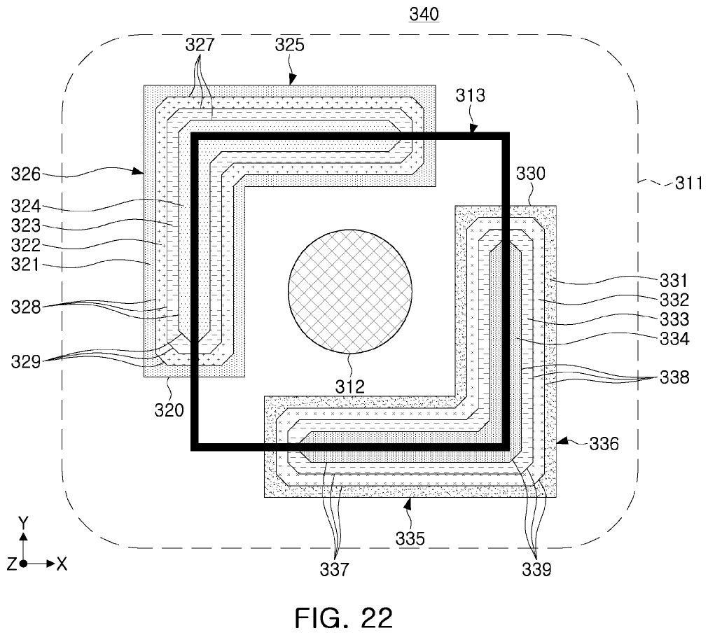

In the example embodiment illustrated in FIG. 22, a semiconductor device 340 may be the same as the semiconductor device 310 of FIG. 21, except for shapes of a first diode 320 and a second diode 330. Impurity zones 322, 324, 332, and 334 may include third boundaries 329 and 339, intersecting a first direction (X-axis direction) and a second direction (Y-axis direction) and extending in a direction that is parallel to an upper surface of a semiconductor substrate 311.

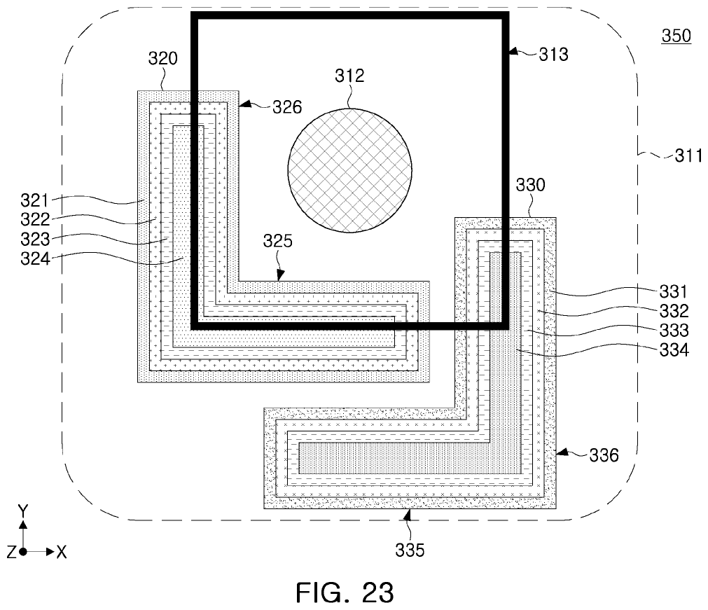

In the example embodiment illustrated in FIG. 23, specifically, a semiconductor device 350 may be the same as the semiconductor device 310 of FIG. 21, except for a position of a first zone 325 being changed. A via structure 252 may be disposed or provided between a first diode 260 and a second diode 270 in a first direction of a semiconductor substrate 251. In other words, a via structure 312 may be disposed or provided between a second zone 326 and a fourth zone 336 in a first direction (X-axis direction in FIG. 23). In addition, a first zone 265 may be disposed or provided between the via structure 312 and a third zone 335 in a second direction (Y-axis direction in FIG. 23).

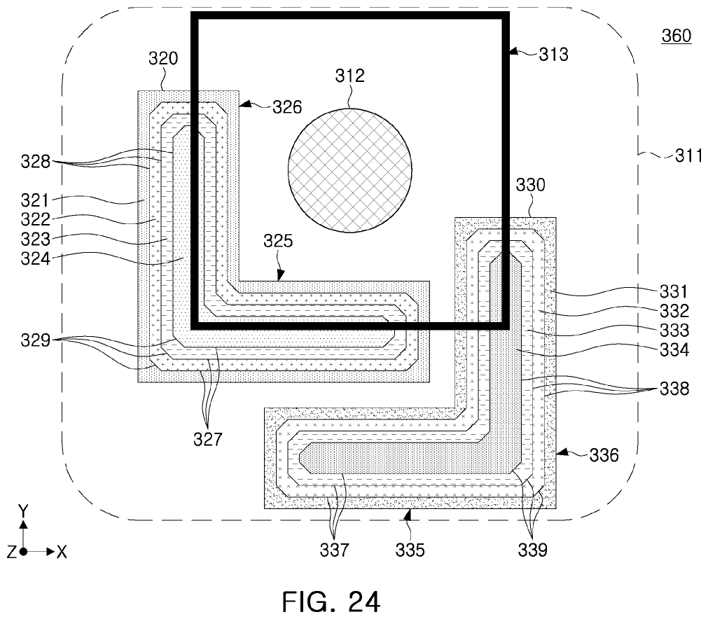

In the example embodiment illustrated in FIG. 24, a semiconductor device 360 may be the same as the semiconductor device 350 of FIG. 23, except for shapes of a first diode 320 and a second diode 330. Impurity zones 322, 324, 332, and 334 may include third boundaries 329 and 339, intersecting a first direction (X-axis direction) and a second direction (Y-axis direction) and extending in a direction that is parallel to an upper surface of a semiconductor substrate 311.

In the example embodiments illustrated in FIGS. 21 to 24, at least one of the first diode 320 and the second diode 330 may have a zone overlapping (or overlap with) the keep-out zone 313. In other words, at least one of the impurity zones 322, 324, 332, and 334, providing the first diode 320 and the second diode 330, may be formed to overlap the keep-out zone 313.

Current driving force of a diode may be proportional to a circumference of an impurity zone. That is, the second diode 330 may be allowed to include the third zone 335 and the fourth zone 336, thereby increasing a circumference of the third impurity zone third zone 332 and a circumference of the fourth impurity zone 334. In addition, a degree of freedom in design may be increased according to an arrangement of a first zone 325 of the first diode 320. The above-described example embodiments may suffer losses in terms of a degree of integration as compared to the example embodiments of FIGS. 17 to 20, but may effectively protect elements from ESD inflowing during processing and/or testing by increasing current driving force of the second diode 330.

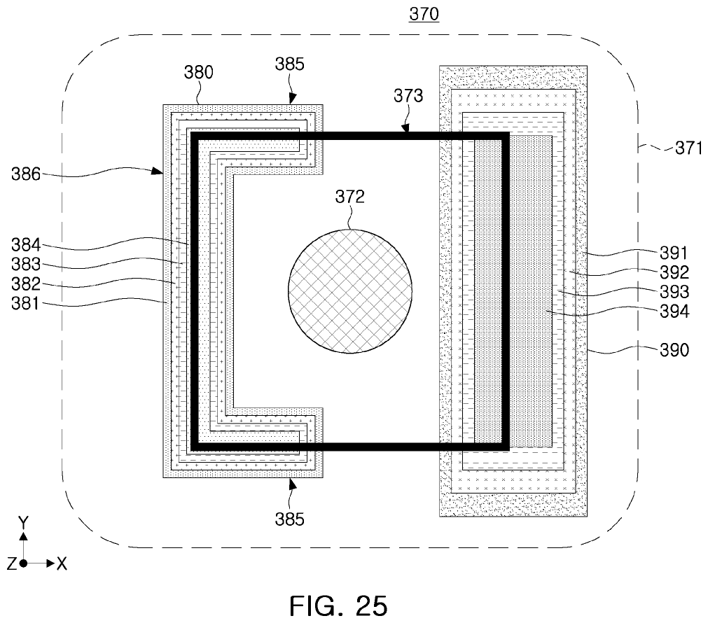

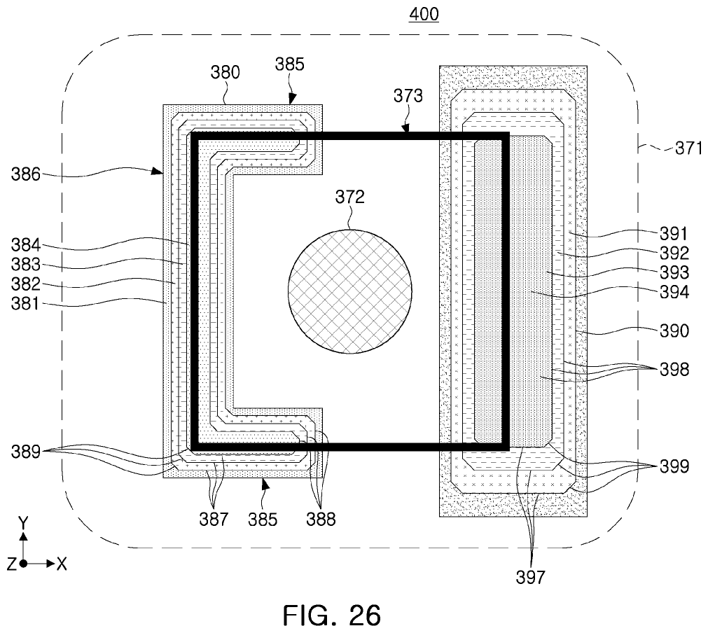

FIGS. 25 and 26 are diagrams illustrating a semiconductor device according to an example embodiment of the disclosure.

FIGS. 25 and 26 are diagrams illustrating semiconductor devices 370 and 400 viewed from above upper surfaces of the semiconductor devices 370 and 400. The semiconductor devices 370 and 400 may include a semiconductor substrate 371, a via structure 372, a keep-out zone 373, a first diode 380, and a second diode 390.

In a similar manner to other example embodiments described above, the via structure 372 may be a through-silicon via, passing through the semiconductor substrate 371. The keep-out zone 373 may be defined around the via structure 372, and may be a zone in no elements are formed in consideration of thermal stress of the via structure 372. Accordingly, elements involved in operations of the semiconductor devices 370 and 400 may be disposed or provided on an outside of the keep-out zone 373.

The first diode 380 and the second diode 390 may be connected to the via structure 372 to provide a current path through which overcurrent, externally inflowing due to ESD, is flowable. As an example, the first diode 380 may be connected between a first power pad, supplying a first power voltage, and the via structure 372, and the second diode 390 may be connected between a second power pad, supplying a second power voltage different from the first power voltage, and the via structure 372. A configuration of each of the first diode 380 and the second diode 390 may be similar to that described above with reference to FIG. 12.

As an example, referring to FIG. 25, the first diode 380, formed in a first well zone 381, may include a first impurity zone 382, a second impurity zone 384, and a first element isolation film 383 disposed or provided therebetween. The second diode 390 may include a third impurity zone 392, a fourth impurity zone 394, and a second element isolation film 393 disposed or provided therebetween, formed in a second well zone 391.

The first diode 380 according to an example embodiment of the disclosure may include a pair of first zones 385 extending in a first direction (X-axis direction in FIG. 25), parallel to an upper surface of the semiconductor substrate 371, and a second zone 386 connecting the pair of first zones 385 to each other. The second zone 386 may extend in a second direction (Y-axis direction in FIG. 25), parallel to the upper surface of the semiconductor substrate 371 and orthogonal to the first direction. The second diode 390 according to an example embodiment of the disclosure may extend in the first direction, and a shape of the first diode 380 may be different from that of the second diode 390.

As an example, the via structure 372 may be disposed or provided between the first diode 380 and the second diode 390 in a first direction of the semiconductor substrate 371. In other words, the via structure 372 may be disposed or provided between the second zone 386 and the second diode 390 in the first direction.

In the example embodiment illustrated in FIG. 26, a semiconductor device 400 may be the same as the semiconductor device 370 of FIG. 25, except for shapes of a first diode 380 and a second diode 390. Impurity zones 382, 384, 392, and 394 may include third boundaries 389 and 399, intersecting a first direction (X-axis direction) and a second direction (Y-axis direction) and extending in a direction that is parallel to an upper surface of a semiconductor substrate 371.

In the example embodiments illustrated in FIGS. 25 and 26, at least one of the first diode 380 and the second diode 390 may have a zone overlapping (or overlap with) the keep-out zone 373. In other words, at least one of the impurity zones 382, 384, 392, and 394, providing the first diode 380 and the second diode 390, may be formed to overlap the keep-out zone 373.

Current driving force of a diode may be proportional to a circumference of an impurity zone. That is, the first diode 380 may be allowed to include the pair of first zones 385, thereby increasing a circumference of the first impurity zone 382 and a circumference of the second impurity zone 384. The above-described example embodiments may suffer losses in terms of a degree of integration as compared to the example embodiments of FIGS. 21 to 24, but may effectively protect elements from ESD inflowing during processing and/or testing by increasing current driving force of the first diode 380.

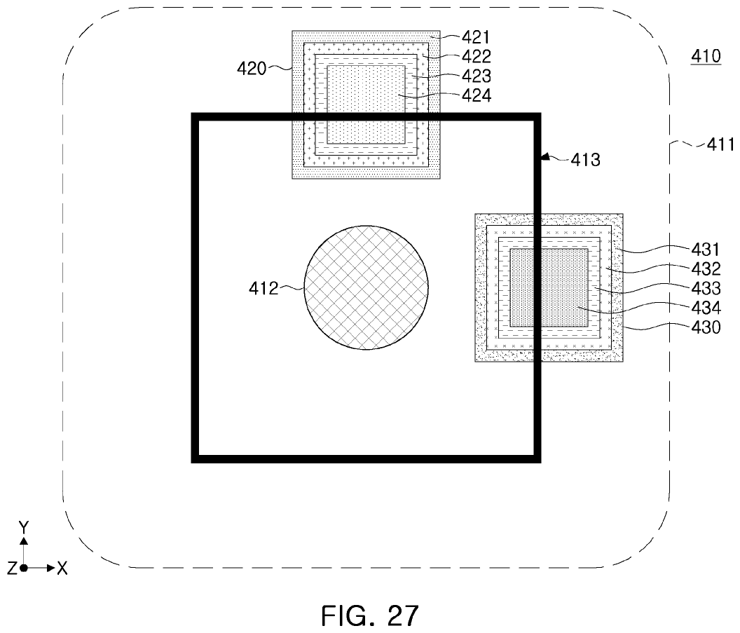

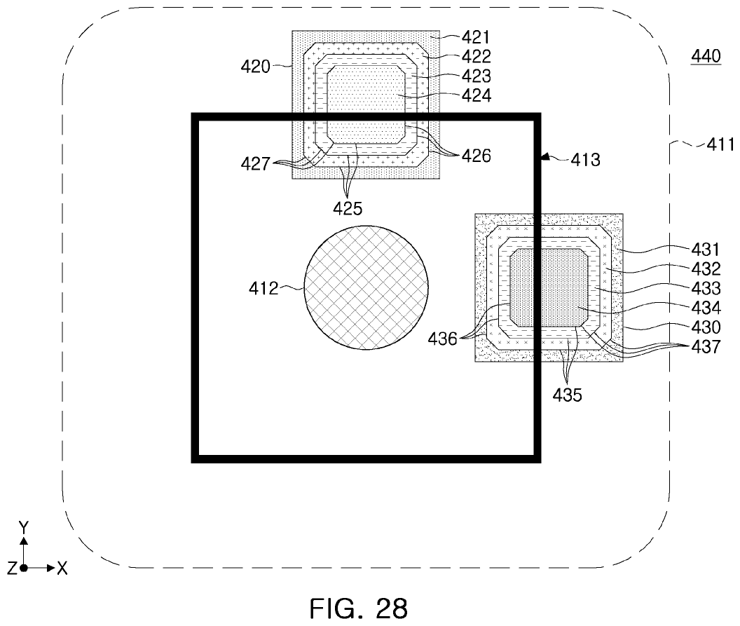

FIGS. 27 and 28 are diagrams illustrating a semiconductor device according to an example embodiment of the disclosure.

FIGS. 27 and 28 may be diagrams illustrating semiconductor devices 410 and 440 viewed from above upper surfaces of the semiconductor devices 410 and 440. The semiconductor devices 410 and 440 may include a semiconductor substrate 411, a via structure 412, a keep-out zone 413, a first diode 420, and a second diode 430.

In a similar manner to other example embodiments described above, the via structure 412 may be a through-silicon via, passing through the semiconductor substrate 411. The keep-out zone 413 may be defined around the via structure 412, and may be a zone in no elements are formed in consideration of thermal stress of the via structure 412. Accordingly, elements involved in operations of the semiconductor devices 410 and 440 may be disposed or provided on an outside of the keep-out zone 413.

The first diode 420 and the second diode 430 may be connected to the via structure 412 to provide a current path through which overcurrent, externally inflowing due to ESD, is flowable. As an example, the first diode 420 may be connected between a first power pad, supplying a first power voltage, and the via structure 412, and the second diode 430 may be connected between a second power pad, supplying a second power voltage different from the first power voltage, and the via structure 412.

A configuration of each of the first diode 420 and the second diode 430 may be similar to that described above with reference to FIG. 12.

As an example, referring to FIG. 27, the first diode 420, formed in a first well zone 421, may include a first impurity zone 422, a second impurity zone 424, and a first element isolation film 423 disposed or provided therebetween. The second diode 430 may include a third impurity zone 432, a fourth impurity zone 434, and a second element isolation film 433 disposed or provided therebetween, formed in a second well zone 431.

According to an example embodiment of the disclosure, the second diode 430 may be adjacent to the via structure 412 in a first direction that is parallel to an upper surface of a semiconductor substrate, and the first diode 420 may be adjacent to the via structure 412 in a second direction that is parallel to the upper surface of the semiconductor substrate and orthogonal to the first direction.

In the example embodiment illustrated in FIG. 28, a semiconductor device 440 may be the same as the semiconductor device 410 of FIG. 27, except for shapes of a first diode 420 and a second diode 430. Impurity zones 422, 424, 432, and 434 may include third boundaries 427 and 437, intersecting a first direction (X-axis direction) and a second direction (Y-axis direction) and extending in a direction that is parallel to an upper surface of a semiconductor substrate 411.

The diodes 420 and 430 according to the example embodiments of FIGS. 27 and 28 may have the same size as the diodes 170 and 180 according to the example embodiments of FIGS. 12 and 13, but arrangements of the first diode 420 and the second diode 430 may be different from each other with respect to the via structure 412. Such a configuration may allow a via structure 412 and a via structure 412 to be connected to each other, such that a space between integrated circuit zones in which semiconductor elements, providing an input/output circuit, are formed may be efficiently used. That is, a degree of freedom in disposing diodes may be increased, thereby efficiently using a semiconductor substrate having a limited area.

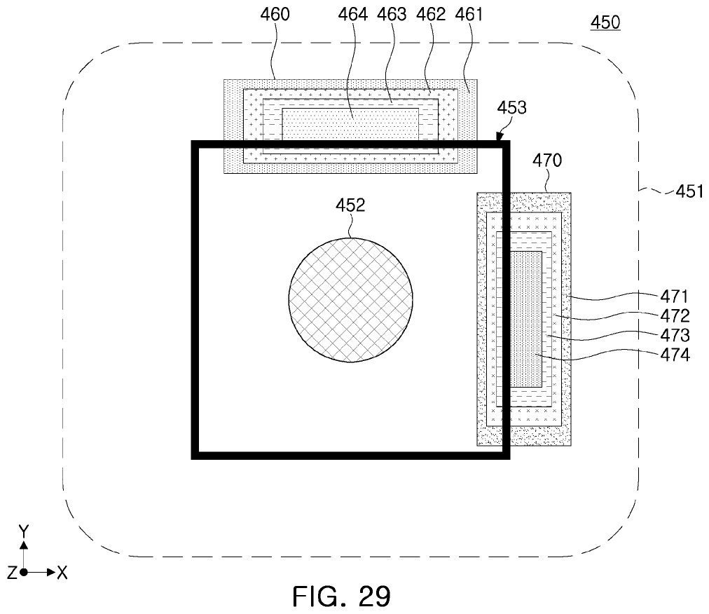

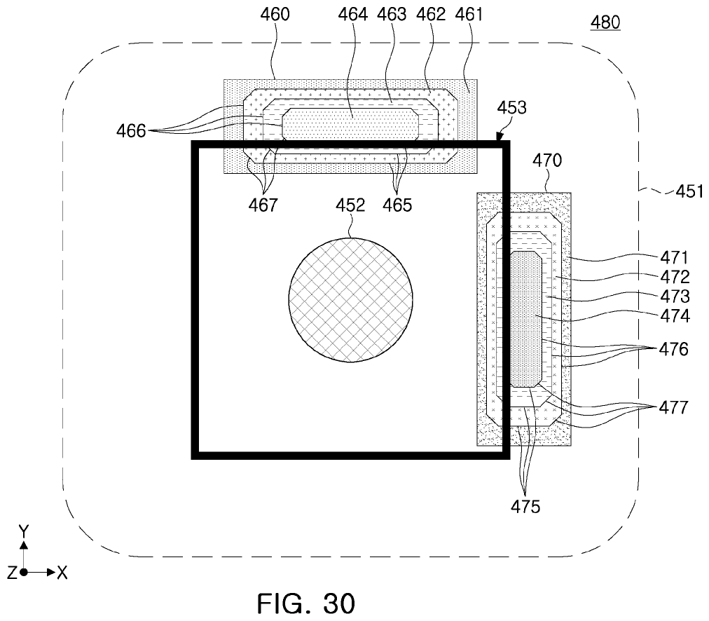

FIGS. 29 and 30 are diagrams illustrating a semiconductor device according to an example embodiment of the disclosure.

FIGS. 29 and 30 may be diagrams illustrating semiconductor devices 450 and 480 viewed from above upper surfaces of the semiconductor devices 450 and 480. The semiconductor devices 450 and 480 may include a semiconductor substrate 451, a via structure 452, a keep-out zone 453, a first diode 460, and a second diode 470.

In a similar manner to other example embodiments described above, the via structure 452 may be a through-silicon via, passing through the semiconductor substrate 451. The keep-out zone 453 may be defined around the via structure 452, and may be a zone in no elements are formed in consideration of thermal stress of the via structure 452. Accordingly, elements involved in operations of the semiconductor devices 450 and 480 may be disposed or provided on an outside of the keep-out zone 453.

The first diode 460 and the second diode 470 may be connected to the via structure 452 to provide a current path through which overcurrent, externally inflowing due to ESD, is flowable. As an example, the first diode 460 may be connected between a first power pad, supplying a first power voltage, and the via structure 452, and the second diode 470 may be connected between a second power pad, supplying a second power voltage different from the first power voltage, and the via structure 452.

A configuration of each of the first diode 460 and the second diode 470 may be similar to that described above with reference to FIG. 12. As an example, referring to FIG. 29, the first diode 460, formed in a first well zone 461, may include a first impurity zone 462, a second impurity zone 464, and a first element isolation film 463 disposed or provided therebetween. The second diode 470 may include a third impurity zone 472, a fourth impurity zone 474, and a second element isolation film 473 disposed or provided therebetween, formed in a second well zone 471.

The first diode 460 according to an example embodiment of the disclosure may extend in a first direction (X-axis direction in FIG. 29), parallel to an upper surface of a semiconductor substrate 451. The second diode 470 according to an example embodiment of the disclosure may extend in a second direction that is parallel to the upper surface of the semiconductor substrate 451 and orthogonal to the first direction. That is, a shape of the first diode 460 may be different from that of the second diode 470.

In the example embodiment illustrated in FIG. 30, a semiconductor device 480 may be the same as the semiconductor device 450 of FIG. 29, except for shapes of a first diode 460 and a second diode 470. Impurity zones 462, 464, 472, and 474 may include third boundaries 467 and 477, intersecting a first direction (X-axis direction) and a second direction (Y-axis direction) and extending in a direction that is parallel to the upper surface of the semiconductor substrate 451.

Arrangements of the first diode 460 and the second diode 470 according to the embodiments of FIGS. 29 and 30 may be the same as those of the example embodiments of FIGS. 27 and 28, but circumferences of the diodes 460 and 470 may be different from those of the example embodiments of FIGS. 27 and 28. A diode may have performance proportional to a circumference of an impurity zone, such that a degree of integration may be reduced as compared to the example embodiments of FIGS. 27 and 28, but current drivability may be increased.

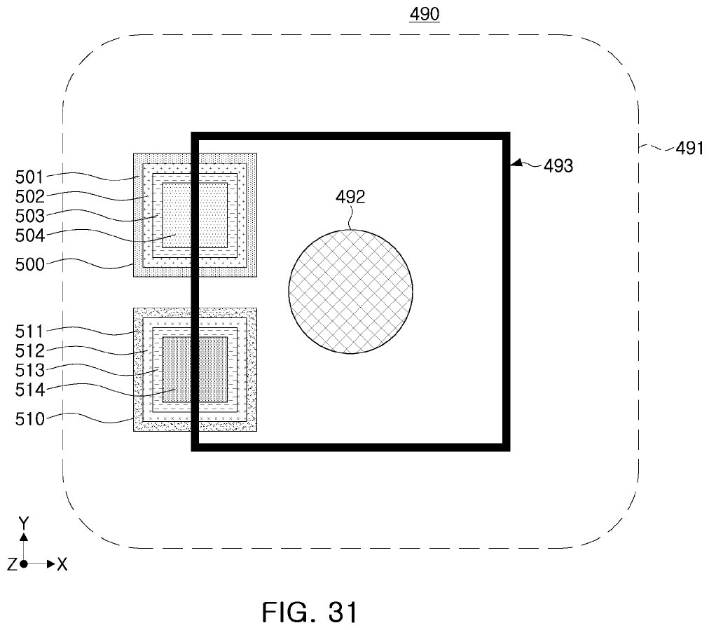

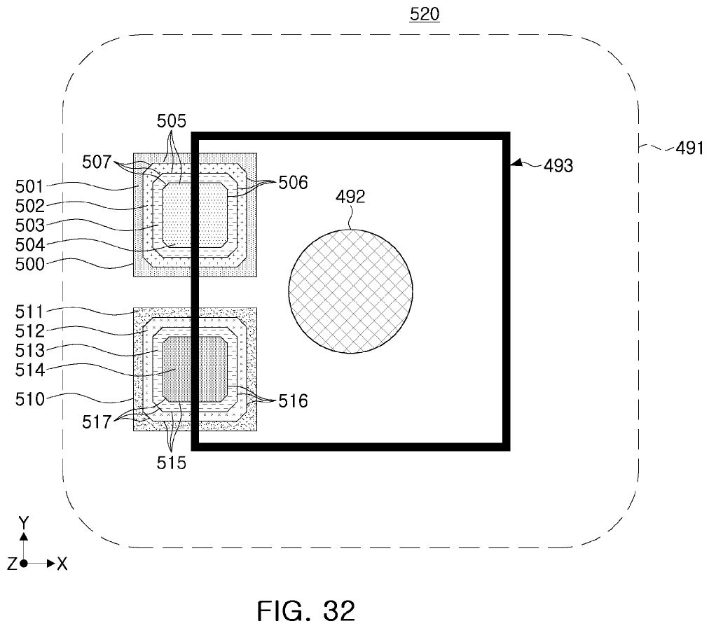

FIGS. 31 and 32 are diagrams illustrating a semiconductor device according to an example embodiment of the disclosure.

FIGS. 31 and 32 may be diagrams illustrating the semiconductor devices 490 and 520 viewed from above upper surfaces of the semiconductor devices 490 and 520. The semiconductor devices 490 and 520 may include a semiconductor substrate 491, a via structure 492, a keep-out zone 493, a first diode 500, and a second diode 510.

In a similar manner to other example embodiments described above, the via structure 492 may be a through-silicon via, passing through the semiconductor substrate 491. The keep-out zone 493 may be defined around the via structure 492, and may be a zone in no elements are formed in consideration of thermal stress of the via structure 492. Accordingly, elements involved in operations of the semiconductor devices 490 and 520 may be disposed or provided on an outside of the keep-out zone 493.

The first diode 500 and the second diode 510 may be connected to the via structure 492 to provide a current path through which overcurrent, externally inflowing due to ESD, is flowable. As an example, the first diode 500 may be connected between a first power pad, supplying a first power voltage, and the via structure 492, and the second diode 510 may be connected between a second power pad, supplying a second power voltage different from the first power voltage, and the via structure 492.

A configuration of each of the first diode 500 and the second diode 510 may be similar to that described above with reference to FIG. 12. As an example, referring to FIG. 31, the first diode 500, formed in a first well zone 501, may include a first impurity zone 502, a second impurity zone 504, and a first element isolation film 503 disposed or provided therebetween. The second diode 510 may include a third impurity zone 512, a fourth impurity zone 514, and a second element isolation film 513 disposed or provided therebetween, formed in a second well zone 511.

The first diode 500 according to an example embodiment of the disclosure may be adjacent to the via structure 492 in a first direction that is parallel to an upper surface of the semiconductor substrate 491, and the second diode 510 may be adjacent to the via structure 492 in the first direction and may be disposed or provided in a position different from that of the first diode 500 in a second direction that is parallel to the upper surface of the semiconductor substrate 491 and orthogonal to the first direction.

In the example embodiment illustrated in FIG. 32, a semiconductor device 520 may be the same as the semiconductor device 490 of FIG. 31, except for shapes of a first diode 500 and a second diode 510. Impurity zones 502, 504, 512, and 514 may include third boundaries 507 and 517, intersecting a first direction (X-axis direction) and a second direction (Y-axis direction) and extending in a direction that is parallel to the upper surface of the semiconductor substrate 491.

An area of an impurity zone of each of the diodes 500 and 510 according to the embodiments of FIGS. 31 and 32 may be the same as an area of an impurity zone of the diode of FIG. 12, but an arrangement of the second diode 510 may be different from that of the diode of FIG. 12. Such a configuration may allow a via structure 492 and a via structure 492 to be connected to each other, such that a space between integrated circuit zones in which semiconductor elements, providing an input/output circuit, are formed may be efficiently used. That is, a degree of freedom in disposing diodes may be increased, thereby efficiently using a semiconductor substrate having a limited area.

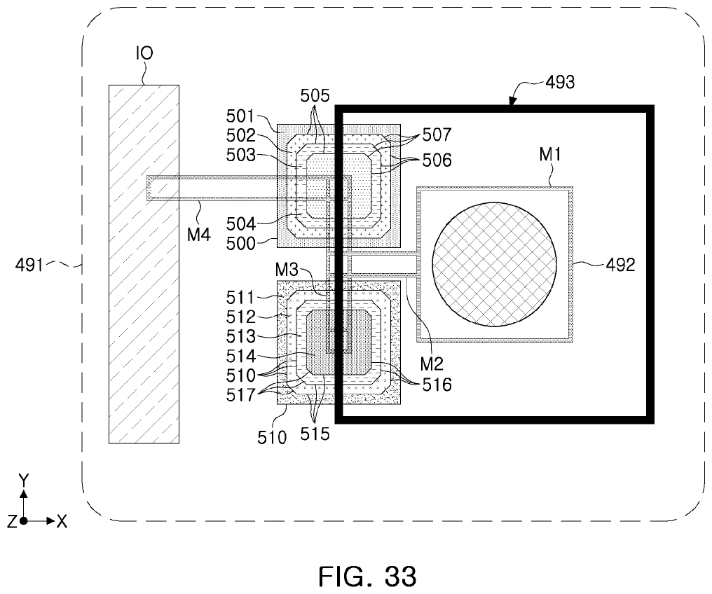

FIG. 33 is a diagram illustrating a connection between input/output elements of the semiconductor device of FIG. 32 according to an example embodiment of the disclosure.

According to an example embodiment of the disclosure, an input/output circuit zone IO, a first diode 500, a second diode 510, and a via structure 492 may be electrically and structurally connected to each other through a metal layer M. Each of metal layers M1 to M4 may be electrically and structurally connected to the input/output circuit zone IO, the first diode 500, the second diode 510, and the via structure 492 through contact structures.

In an example embodiment, the via structure 492 may be connected to M1. A second impurity zone 504 of the first diode 500 and a fourth impurity zone 514 of the second diode 510 may be connected to each other through M3. M1 and M3 may be connected to each other through M2. The second impurity zone 504 of the first diode 500 may be connected to the input/output circuit zone IO through M4.

A semiconductor device according to an example embodiment of the disclosure may include a pair of diodes having a zone overlapping a keep-out zone of a via structure passing through a semiconductor substrate. In addition, a shape of a diode may be properly designed to increase performance of the diode, thereby effectively preventing defects that may occur in a semiconductor device due to ESD.

While example embodiments have been illustrated and described above, it will be apparent to those skilled in the art that modifications and variations could be made without departing from the scope of the disclosure as defined by the appended claims.

What is claimed is:

1. A semiconductor device comprising:
a semiconductor substrate;
a via structure passing through the semiconductor substrate;
a first diode comprising a first impurity zone doped with a first conductivity-type impurity and a second impurity zone doped with a second conductivity-type impurity; and
a second diode comprising a third impurity zone doped with the first conductivity-type impurity and a fourth impurity zone doped with the second conductivity-type impurity,
wherein the second conductivity-type impurity is different from the first conductivity-type impurity, and
wherein at least one of the first impurity zone, the second impurity zone, the third impurity zone, and the fourth impurity zone overlaps with a keep-out zone of the via structure.

2. The semiconductor device of claim 1, wherein the via structure is provided between the first diode and the second diode in a first direction that is parallel to an upper surface of the semiconductor substrate.

3. The semiconductor device of claim 2, wherein the first diode comprises a first zone extending in the first direction and a second zone extending in a second direction that is parallel to the upper surface of the semiconductor substrate and orthogonal to the first direction, and
wherein the via structure is provided between the second zone and the second diode in the first direction.

4. The semiconductor device of claim 3, wherein the second diode extends in the second direction.

5. The semiconductor device of claim 3, wherein the second diode comprises a third zone extending in the first direction and a fourth zone extending in the second direction.

6. The semiconductor device of claim 2, wherein the first diode comprises a pair of first zones extending in the first direction and a second zone connecting the pair of first zones to each other, the second zone extending in a second direction that is parallel to the upper surface of the semiconductor substrate and orthogonal to the first direction, and
the via structure is provided between the second zone and the second diode in the first direction.

7. The semiconductor device of claim 1, wherein the second diode is adjacent to the via structure in a first direction that is parallel to an upper surface of the semiconductor substrate, and
wherein the first diode is adjacent to the via structure in a second direction that is parallel to the upper surface of the semiconductor substrate and orthogonal to the first direction.

8. The semiconductor device of claim 1, wherein the first diode is adjacent to the via structure in a first direction that is parallel to an upper surface of the semiconductor substrate, and
wherein the second diode is adjacent to the via structure in the first direction, and is provided in a position different from that of the first diode in a second direction that is parallel to the upper surface of the semiconductor substrate and orthogonal to the first direction.

9. The semiconductor device of claim 1, wherein each of the first impurity zone, the second impurity zone, the third impurity zone, and the fourth impurity zone comprises:
a first boundary extending in a first direction that is parallel to an upper surface of the semiconductor substrate, and
a second boundary extending in a second direction that is parallel to the upper surface of the semiconductor substrate and orthogonal to the first direction, and
wherein at least one of the first impurity zone, the second impurity zone, the third impurity zone, and the fourth impurity zone comprises a third boundary extending in a third direction that intersects the first direction and the second direction.

10. The semiconductor device of claim 1, wherein the first impurity zone and the second impurity zone are provided in a first well zone on a substrate,
wherein the first well zone is doped with an N-type impurity, and
wherein at least a portion of the first well zone overlaps with an N well zone of an input/output element.

11. A semiconductor device comprising:
a semiconductor substrate;
a via structure passing through the semiconductor substrate;
a first diode comprising a first impurity zone and a second impurity zone; and
a second diode comprising a third impurity zone and a fourth impurity zone,
wherein at least one of the first diode and the second diode overlaps with a keep-out zone of the via structure, and
wherein a first shape of the first diode is different from a second shape of the second diode.

12. The semiconductor device of claim 11, wherein the first diode comprises:
a first zone extending in a first direction that is parallel to an upper surface of the semiconductor substrate, and
a second zone extending in a second direction that is parallel to the upper surface of the semiconductor substrate and orthogonal to the first direction.

13. The semiconductor device of claim 12, wherein the second diode extends in the second direction.

14. The semiconductor device of claim 12, wherein the second diode comprises a third zone extending in the first direction and a fourth zone extending in the second direction.

15. The semiconductor device of claim 11, wherein the first diode comprises a pair of first zones extending in a first direction that is parallel to an upper surface of the semiconductor substrate and a second zone connecting the pair of first zones to each other, the second zone extending in a second direction that is parallel to the upper surface of the semiconductor substrate and orthogonal to the first direction.

16. The semiconductor device of claim 11, wherein the first diode extends in a first direction that is parallel to an upper surface of the semiconductor substrate, and
the second diode extends in a second direction that is parallel to the upper surface of the semiconductor substrate and orthogonal to the first direction.

17. The semiconductor device of claim 11, wherein
each of the first impurity zone, the second impurity zone, the third impurity zone, and the fourth impurity zone comprises a first boundary extending in a first direction that is parallel to an upper surface of the semiconductor substrate and comprises a second boundary extending in a second direction that is parallel to the upper surface of the semiconductor substrate and orthogonal to the first direction, and
at least one of the first impurity zone, the second impurity zone, the third impurity zone, and the fourth impurity zone comprises a third boundary extending in a third direction that intersects the first direction and the second direction.

18. The semiconductor device of claim 11, wherein
the first impurity zone and the second impurity zone are provided in a first well zone formed on a substrate, and the first well zone is doped with an N-type impurity, and
at least a portion of the first well zone comprises a zone overlapping an N well zone of an input/output element.

19. A semiconductor device comprising:
a first power pad receiving a first power supply voltage;
a second power pad receiving a second power supply voltage lower than the first power supply voltage;
a via structure passing through the semiconductor substrate;
a signal pad exchanging a signal, the signal pad operatively connected to the via structure;
a first diode comprising a first impurity zone and a second impurity zone, the first diode being connected between the signal pad and the first power pad; and
a second diode comprising a third impurity zone and a fourth impurity zone, the second diode being connected between the signal pad and the second power pad,
wherein at least one of the first diode and the second diode is provided in a zone between the via structure and an integrated circuit zone,
wherein semiconductor elements are formed in the zone,
wherein the semiconductor elements provide an input/output circuit connected to the via structure,
wherein each of the first impurity zone, the second impurity zone, the third impurity zone, and the fourth impurity zone comprises a first boundary extending in a first direction that is parallel to an upper surface of the semiconductor substrate and comprises a second boundary extending in a second direction that is parallel to the upper surface of the semiconductor substrate and orthogonal to the first direction, and
wherein at least one of the first impurity zone, the second impurity zone, the third impurity zone, and the fourth impurity zone comprises a third boundary extending in a third direction that intersects the first direction and the second direction.

20. The semiconductor device of claim 19, wherein the via structure is provided between the first diode and the second diode in the first direction.
